(19) United States
(12) Patent Application Publication
(10) Pub. No.: US 2020/0234786 A1
(43) Pub. Date: Jul. 23, 2020

(54) DATA READING METHOD, STORAGE CONTROLLER AND STORAGE DEVICE

(71) Applicant: Shenzhen EpoStar Electronics Limited CO., Shenzhen (CN)

(72) Inventor: Yu-Hua Hsiao, Hsinchu County (TW)

(73) Assignee: Shenzhen EpoStar Electronics Limited CO., Shenzhen (CN)

(21) Appl. No.: 16/402,247

(22) Filed: May 3, 2019

(30) Foreign Application Priority Data
Jan. 19, 2019 (TW) 108102145

(51) Int. Cl. G11C 29/50; G11C 16/04; G11C 16/10; G11C 16/26

(52) U.S. Cl. CPC G11C 29/50004; G11C 16/0483; G11C 11/5628; G11C 16/26; G11C 16/10

(57) ABSTRACT

A memory management method is provided. The method includes performing a read voltage optimization operation corresponding to a target physical page among a plurality of physical pages on a target word line to obtain an optimized read voltage set and using the optimized read voltage set to read the target word line after the read voltage optimization operation is completed. The read voltage optimization operation includes: identifying P test codes corresponding to the target physical page and Q transition read voltages corresponding to the P test codes; using the Q transition read voltages and corresponding Q test read voltage sets to read the target word line to obtain Q test code count difference sets; and obtaining the optimized read voltage set according to the Q test code count difference set.

### CROSS-REFERENCE TO RELATED APPLICATION

This application claims the priority benefit of Taiwan application serial no. 108102145, filed on Jan. 19, 2019. The entirety of the above-mentioned patent application is hereby incorporated by reference herein and made a part of this specification.

### BACKGROUND

### Technical Field

The invention relates to a data reading method, and more particularly, to a data reading method adapted to a storage device having a rewritable non-volatile memory module and a storage controller.

### Description of Related Art

In general, when reading data from a rewritable non-volatile memory module, if the read failure does not occur, a system will use a preset read voltage set or a previously used optimized read voltage set to read the data. The system (a storage system) does not use the preset read voltage set or the previously used optimized read voltage set but adjusts the read voltage set accordingly only when the read failure occurs.

However, in most of the conventional approaches for adjusting the read voltage set to obtain the optimized read voltage set thereby reading the data, an optimization is focused on the read voltage set corresponding to a target word line while ignoring the fact that the read failure is less likely caused by all of the physical pages of the target word line. For a specific physical page of the target word line with a poorer read state (e.g., a target physical page with higher error bit count), the common conventional approaches cannot perform a read voltage optimization operation in page-level only on a transition read voltage for identifying the specific physical page. Alternatively, even if the conventional approaches can perform the read voltage optimization operation on the specific physical page, only one transition read voltage may be adjusted at a time in the conventional approaches. This will require a large number of reading operations, which significantly reduce efficiency of the optimization operation.

In other words, it would take a considerable amount of resources in the conventional approaches to execute the read voltage optimization operation for the entire target word line before an optimized read voltage may be obtained as the transition read voltage corresponding to the specific physical page. Consequently, the efficiency of reading data is reduced.

Therefore, how to quickly and efficiently optimize the transition read voltage for identifying storage states of the specific physical page without preparing verified data in order to solve the problem in the conventional approaches, improve the efficiency of reading data and reduce loadings in a decoding operation for the rewritable non-volatile memory module is one of issues to be addressed by persons skilled in art.

Nothing herein should be construed as an admission of knowledge in the prior art of any portion of the present invention. Furthermore, citation or identification of any document in this application is not an admission that such document is available as prior art to the present invention, or that any reference forms a part of the common general knowledge in the art.

### SUMMARY

The invention provides a data reading method, a storage controller and a storage device, which are capable of quickly and efficiently obtaining an accurate optimized read voltage set in page-level. Accordingly, the optimized read voltage set may be used to correctly read data from the corresponding physical page and thereby improve the efficiency of reading data.

An embodiment of the invention provides a data reading method adapted to a storage device disposed with a rewritable non-volatile memory module. The rewritable non-volatile memory module has a plurality of word lines. Each word line among the word lines is coupled to a plurality of memory cells. Each memory cell among the memory cells includes a plurality of physical pages, and each physical page among the physical pages is configured to be programmed as a bit value. The method includes: selecting a target word line among the word lines of the rewritable non-volatile memory module, and performing a read voltage optimization operation corresponding to a target physical page among the physical pages on the target word line, wherein a plurality of target memory cells of the target word line are already programmed. The read voltage optimization operation includes: identifying P test codes corresponding to the target physical page, and identifying Q transition read voltages corresponding to the P test codes in a preset read voltage set according to the preset read voltage set corresponding to the target word line, wherein the Q transition read voltages are configured to divide a plurality of storage states of the target physical page, wherein P is a positive integer, and Q is a positive integer less than P; setting Q test read voltage sets respectively corresponding to the Q transition read voltages, wherein each of the Q test read voltage sets includes X test read voltages, and voltage values of the X test read voltages are set by a voltage value of the corresponding transition read voltage and a test voltage offset, wherein X is a positive integer; using the Q transition read voltages and the corresponding Q test read voltage sets to read the target word line to obtain Q test code count difference sets corresponding to the Q test read voltage sets; and obtaining an optimized read voltage set corresponding to the target physical page according to the Q test code count difference sets, so as to completing the read voltage optimization operation corresponding to the target physical page; and using the optimized read voltage set to read the target word line after the read voltage optimization operation corresponding to the target physical page is completed.

An embodiment of the invention provides a storage controller, which is configured to control a storage device having a rewritable non-volatile memory module. The storage controller includes a connection interface circuit, a memory interface control circuit, a read voltage management circuit unit and a processor. The connection interface circuit is configured to couple to a host system. The memory interface control circuit is configured to couple to the rewritable non-volatile memory module. The rewritable non-volatile memory module has a plurality of word lines. Each word line among the word lines is coupled to a plurality of memory cells. Each memory cell among the memory cells includes a plurality of physical pages, and each physical page among the physical pages is configured to be programmed as a bit value. The processor is coupled to the connection interface circuit, the memory interface control circuit and the read voltage management circuit unit. The processor selects a target word line among the word lines of the rewritable non-volatile memory module, and instructs the read voltage management circuit unit to perform a read voltage optimization operation corresponding to a target physical page among the physical pages on the target word line, wherein a plurality of target memory cells of the target word line are already programmed. In the read voltage optimization operation, the read voltage management circuit unit is configured to identify P test codes corresponding to the target physical page, and identify Q transition read voltages corresponding to the P test codes in a preset read voltage set according to the preset read voltage set corresponding to the target word line, wherein the Q transition read voltages are configured to divide a plurality of storage states of the target physical page, wherein P is a positive integer, and Q is a positive integer less than P. The read voltage management circuit unit is further configured to set Q test read voltage sets respectively corresponding to the Q transition read voltages, wherein each of the Q test read voltage sets includes X test read voltages, and voltage values of the X test read voltages are set by a voltage value of the corresponding transition read voltage and a test voltage offset, wherein X is a positive integer. The read voltage management circuit unit is further configured to use the Q transition read voltages and the corresponding Q test read voltage sets to read the target word line to obtain Q test code count difference sets corresponding to the Q test read voltage sets. The read voltage management circuit unit is further configured to obtain an optimized read voltage set corresponding to the target physical page according to the Q test code count difference sets, so as to complete the read voltage optimization operation corresponding to the target physical page. The processor is further configured to use the optimized read voltage set to read the target word line after the read voltage optimization operation corresponding to the target physical page is completed.

An embodiment of the invention provides a storage device. The storage device includes a rewritable non-volatile memory module, a memory interface control circuit and a processor. The rewritable non-volatile memory module has a plurality of word lines. Each word line among the word lines is coupled to a plurality of memory cells. Each memory cell among the memory cells includes a plurality of physical pages, and each physical page among the physical pages is configured to be programmed as a bit value. The memory interface control circuit is configured to couple to the rewritable non-volatile memory module. The processor is coupled to the memory interface control circuit. The processor loads in and executes a read voltage management program code module to realize a data reading method. The data reading method includes: selecting a target word line among the word lines of the rewritable non-volatile memory module, and performing a read voltage optimization operation corresponding to a target physical page among the physical pages on the target word line, wherein a plurality of target memory cells of the target word line are already programmed. The read voltage optimization operation includes: identifying P test codes corresponding to the target physical page, and identifying Q transition read voltages corresponding to the P test codes in a preset read voltage set according to the preset read voltage set corresponding to the target word line, wherein the Q transition read voltages are configured to divide a plurality of storage states of the target physical page, wherein P is a positive integer, and Q is a positive integer less than P; setting Q test read voltage sets respectively corresponding to the Q transition read voltages, wherein each of the Q test read voltage sets includes X test read voltages, and voltage values of the X test read voltages are set by a voltage value of the corresponding transition read voltage and a test voltage offset, wherein X is a positive integer; using the Q transition read voltages and the corresponding Q test read voltage sets to read the target word line to obtain Q test code count difference sets corresponding to the Q test read voltage sets; and obtaining an optimized read voltage set corresponding to the target physical page according to the Q test code count difference sets, so as to complete the read voltage optimization operation corresponding to the target physical page; and using the optimized read voltage set to read the target word line after the read voltage optimization operation corresponding to the target physical page is completed.

Based on the above, the data reading method, the storage controller and the storage device provided by the embodiments of the invention can execute the read voltage optimization operation corresponding to the target physical page of the target word line on any programmed target word line without preparing verified data. In the read voltage optimization operation, the storage controller identifies a plurality of test codes corresponding to the target physical page and one or more transition read voltages corresponding to the test codes, sets one or more test read voltage sets according to said one or more transition read voltages, and uses said one or more test read voltage sets to read the target word line to obtain a plurality of test code count difference sets. In this way, a target test read voltage (a.k.a. the optimized read voltage) may be identified from the test read voltages in each of the test read voltage sets according to the test code count difference sets, and the preset read voltage set may be changed to the optimized read voltage set corresponding to the target physical page and containing the optimized read voltages, so as to complete the read voltage optimization operation corresponding to the target physical page. After the read voltage optimization operation corresponding to the target physical page is completed, not only can the optimized read voltage set corresponding to the target physical page be found efficiently, the optimized read voltage set may further be used to read the target word line to improve accuracy of the data read from the target word line and improve overall efficiency in the data reading operation.

To make the above features and advantages of the disclosure more comprehensible, several embodiments accompanied with drawings are described in detail as follows.

It should be understood, however, that this Summary may not contain all of the aspects and embodiments of the present disclosure, is not meant to be limiting or restrictive in any manner, and that the disclosure as disclosed herein is and will be understood by those of ordinary skill in the art to encompass obvious improvements and modifications thereto.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram illustrating a host system and a storage device according to an embodiment of the invention.

FIG. 2A is a flowchart illustrating a data reading method according to an embodiment of the invention.

FIG. 2B is a flowchart illustrating step S24 of FIG. 2A according to an embodiment of the invention.

FIGS. 3A-3B are flowcharts illustrating a test code setting method according to an embodiment of the invention.

FIG. 4 is a schematic diagram illustrating threshold voltage distributions of a plurality of memory cells corresponding to N gray codes read through a read voltage set and storage states of the corresponding physical page according to an embodiment of the invention.

FIG. 5 is a schematic diagram for setting lower physical page test codes according to an embodiment of the invention.

FIG. 6 is a schematic diagram for setting middle physical page test codes according to an embodiment of the invention.

FIG. 7A, FIG. 7B and FIG. 7C are schematic diagrams for setting upper physical page test codes according to an embodiment of the invention.

FIG. 8A is a schematic diagram for setting a test code corresponding to a first read voltage mode according to an embodiment of the invention.

FIG. 8B is a schematic diagram for setting a test code corresponding to a second read voltage mode according to an embodiment of the invention.

FIG. 9A is a schematic diagram illustrating a leftward adjusted transition read voltage and a rightward adjusted transition read voltage corresponding to a lower physical page according to an embodiment of the invention.

FIG. 9B is a schematic diagram illustrating a leftward adjusted transition read voltage and a rightward adjusted transition read voltage corresponding to a lower physical page according to another embodiment of the invention.

FIG. 10 is a schematic diagram illustrating a leftward adjusted transition read voltage and a rightward adjusted transition read voltage corresponding to a middle physical page according to an embodiment of the invention.

FIG. 11 is a schematic diagram illustrating a leftward adjusted transition read voltage and a rightward adjusted transition read voltage corresponding to an upper physical page according to an embodiment of the invention.

FIG. 12 is a schematic diagram for setting a test read voltage set corresponding to a transition read voltage of the lower physical page according to an embodiment of the invention.

FIG. 13 is a schematic diagram for setting a plurality of test read voltage sets corresponding to a plurality of transition read voltages of the middle physical page according to an embodiment of the invention.

FIGS. 14A and 14B are schematic diagrams for setting a plurality of test read voltage sets corresponding to a plurality of transition read voltages of the upper physical page according to an embodiment of the invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

Embodiments of the present invention may comprise any one or more of the novel features described herein, including in the Detailed Description, and/or shown in the drawings. As used herein, “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

It is to be noted that the term “a” or “an” entity refers to one or more of that entity. As such, the terms “a” (or “an”), “one or more” and “at least one” can be used interchangeably herein.

In this embodiment, a storage device includes a rewritable non-volatile memory module and a storage device controller (a.k.a. a storage controller or a storage control circuit). Also, the storage device is usually used together with a host system so the host system can write data into or read data from the storage device.

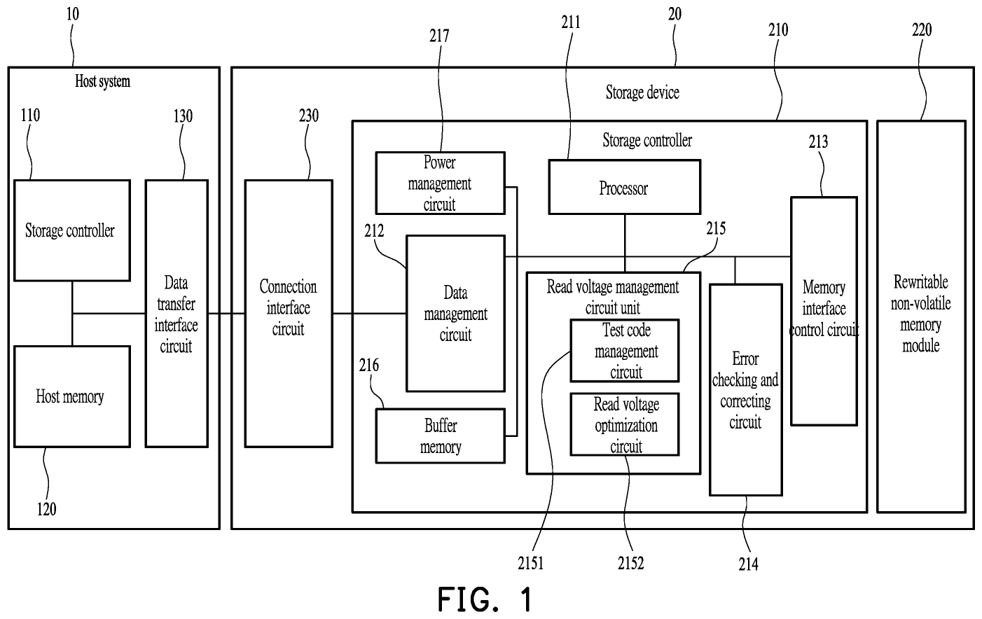

FIG. 1 is a block diagram illustrating a host system and a storage device according to an embodiment of the invention.

With reference to FIG. 1, a host system 10 includes a processor 110, a host memory 120 and a data transfer interface circuit 130. In this embodiment, the data transfer interface circuit 130 is coupled to (or, electrically connected to) the processor 110 and the host memory 120. In another embodiment, the processor 110, the host memory 120 and the data transfer interface circuit 130 are coupled to one another by utilizing a system bus.

A storage device 20 includes a storage controller 210, a rewritable non-volatile memory module 220 and a connection interface circuit 230. Among them, the storage controller 210 includes a processor 211, a data management circuit 212 and a memory interface control circuit 213.

In this embodiment, the host system 10 is coupled to the storage device 20 through the data transfer interface circuit 130 and the connection interface circuit 230 of the storage device 20 to perform a data accessing operation. For example, the host system 10 can store data to the storage device 20 or read data from the storage device 20 through the data transfer interface circuit 130.

In the present embodiment, the processor 110, the host memory 120 and the data transfer interface circuit 130 may be disposed on a main board of the host system 10. The number of the data transfer interface circuit 130 may be one or more. Through the data transfer interface circuit 130, the main board may be coupled to the storage device 20 in a wired manner or a wireless manner. The storage device 20 may be, for example, a flash drive, a memory card, a solid state drive (SSD) or a wireless memory storage device. The wireless memory storage device may be, for example, a memory storage device based on various wireless communication technologies, such as a NFC (Near Field Communication) memory storage device, a WiFi (Wireless Fidelity) memory storage device, a Bluetooth memory storage device, a BLE (Bluetooth low energy) memory storage device (e.g., iBeacon). Further, the main board may also be coupled to various I/O devices including a GPS (Global Positioning System) module, a network interface card, a wireless transmission device, a keyboard, a monitor and a speaker through the system bus.

In this embodiment, the data transfer interface circuit 130 and the connection interface circuit 230 are an interface circuit compatible with a Peripheral Component Interconnect Express (PCI Express) interface standard. Further, a data transfer is performed between the data transfer interface circuit 130 and the connection interface circuit 230 by using a communication protocol of a Non-Volatile Memory express (NVMe) interface standard.

Nevertheless, it should be understood that the invention is not limited to the above. The data transfer interface circuit 130 and the connection interface circuit 230 may also be compatible to a PATA (Parallel Advanced Technology Attachment) standard, an IEEE (Institute of Electrical and Electronic Engineers) 1394 standard, a USB (Universal Serial Bus) standard, a SD interface standard, a UHS-I (Ultra High Speed-I) interface standard, a UHS-II (Ultra High Speed-II) interface standard, a MS (Memory Stick) interface standard, a Multi-Chip Package interface standard, a MMC (Multi Media Card) interface standard, an eMMC interface standard, a UFS (Universal Flash Storage) interface standard, an eMCP interface standard, a CF interface standard, an IDE (Integrated Device Electronics) interface standard or other suitable standards. Further, in another embodiment, the connection interface circuit 230 and the storage controller 210 may be packaged into one chip, or the connection interface circuit 230 is distributed outside a chip containing the storage controller 210.

In this embodiment, the host memory 120 is configured to temporarily store commands executed by the processor 110 or data. For instance, in the present exemplary embodiment, the host memory 120 may be a Dynamic Random Access Memory (DRAM), or a Static Random Access Memory (SRAM) and the like. Nevertheless, it should be understood that the invention is not limited in this regard, and the host memory 120 may also be other appropriate memories.

The storage unit 210 is configured to execute a plurality of logic gates or control commands, which are implemented in a hardware form or in a firmware form, and to perform operations of writing, reading or erasing data in the rewritable non-volatile memory storage module 220 according to the commands of the host system 10.

More specifically, the processor 211 in the storage controller 210 is a hardware with computing capabilities, which is configured to control overall operation of the storage controller 210. Specifically, the processor 211 has a plurality of control commands and the control commands are executed to perform various operations such as writing, reading and erasing data during operation of the storage device 20.

It is noted that, in this embodiment, the processor 110 and the processor 211 are, for example, a central processing unit (CPU), a micro-processor, other programmable microprocessors, a digital signal processor (DSP), a programmable controller, an application specific integrated circuits (ASIC), a programmable logic device (PLD) or other similar circuit elements, which are not particularly limited by the invention.

In an embodiment, the storage controller 210 further includes a ROM (not illustrated) and a RAM (not illustrated). More particularly, the ROM has a boot code, which is executed by the processor 221 to load the control commands stored in the rewritable non-volatile memory module 220 into the RAM of the storage controller 210 when the storage controller 210 is enabled. Then, the control commands are executed by the processor 211 to perform operations, such as writing, reading or erasing data. In another embodiment, the control commands of the processor 211 may also be stored as program codes in a specific area (for example, physical storage units in the rewritable non-volatile memory module 220 dedicated for storing system data) of the rewritable non-volatile memory module 220.

In this embodiment, as described above, the storage controller 210 further includes the data management circuit 212 and the memory interface control circuit 213. It should be noted that, operations performed by each part of the storage controller 210 may also be considered as operations performed by the storage controller 210.

The data management circuit 212 is coupled to the processor 211, the memory interface control circuit 213 and the connection interface circuit 230. The data management circuit 212 is configured to transmit data under instruction of the processor 211. For example, the data may be read from the host system 10 (e.g., the host memory 120) through the connection interface circuit 230, and the read data may be written into the rewritable non-volatile memory module 220 through the memory interface control circuit 213 (e.g., a writing operation performed according to a write command from the host system 10). As another example, the data may be read from one or more physical units of the rewritable non-volatile memory module 220 through the memory interface control circuit 213 (the data may be read from one or more memory cells in one or more physical units), and the read data may be written into the host system 10 (e.g., the host memory 120) through the connection interface circuit 230 (e.g., a reading operation performed according to a read command from the host system 10). In another embodiment, the data management circuit 212 may also be integrated into the processor 211.

The memory interface control circuit 213 is configured to perform write (or, programming) operation, read operation and erase operation for the rewritable non-volatile memory module 220 together with the data management circuit 212 under instruction of the processor 211.

For instance, the processor 211 can execute a write command sequence to instruct the memory interface control circuit 213 to write the data into the rewritable non-volatile memory module 220; the processor 211 can execute a read command sequence to instruct the memory interface control circuit 213 to read the data from one or more physical units (a.k.a. target physical units) corresponding to the read command in the rewritable non-volatile memory module 220; the processor 211 can execute an erase command sequence to instruct the memory interface control circuit 213 to perform the erasing operation for the rewritable non-volatile memory module 220. Each of the write command sequence, the read command sequence and the erase command sequence may include one or more program codes or command codes, respectively, and instruct the rewritable non-volatile memory module 220 to perform the corresponding operations, such as writing, reading and erasing. In an embodiment, the processor 211 can further give other command sequences to the memory interface control circuit 213 so as to perform the corresponding operations for the rewritable non-volatile memory module 220.

In addition, data to be written to the rewritable non-volatile memory module 220 is converted into a format acceptable by the rewritable non-volatile memory module 220 through the memory interface control circuit 213. Specifically, when the processor 211 intends to access the rewritable non-volatile memory module 220, the processor 211 sends the corresponding command sequences to the memory interface control circuit 213 in order to instruct the memory interface control circuit 213 to perform the corresponding operations. For example, the command sequences may include the write command sequence as an instruction for writing data, the read command sequence as an instruction for reading data, the erase command sequence as an instruction for erasing data, and other corresponding command sequences as instructions for various memory operations (e.g., changing a plurality of default read voltage values of a default read voltage set for the reading operation or performing a garbage collection procedure). The command sequences may include one or more signals, or data from the bus. The signals or the data may include command codes and program codes. For example, information such as identification codes and memory addresses are included in the read command sequence.

The rewritable non-volatile memory module 220 is coupled to the storage controller 210 (the memory control circuit unit 213) and configured to store data written from the host system 10. The rewritable non-volatile memory module 220 may be a SLC (Single Level Cell) NAND flash memory module (i.e., a flash memory module capable of storing one bit in one memory cell), an MLC (Multi Level Cell) NAND flash memory module (i.e., a flash memory module capable of storing two bits in one memory cell), a TLC (Triple Level Cell) NAND flash memory module (i.e., a flash memory module capable of storing three bits in one memory cell),a QLC (Quadruple Level Cell) NAND flash memory module (i.e., a flash memory module capable of storing four bits in one memory cell), a 3D NAND flash memory module or a vertical NAND flash memory module, a vertical NAND flash memory module or a vertical NAND flash memory module other flash memory modules or any memory module having the same features. The memory cells in the rewritable non-volatile memory module 220 are disposed in an array.

In this embodiment, the rewritable non-volatile memory module 220 has a plurality of word lines, wherein each word line among the word lines is coupled to a plurality of memory cells. The memory cells on the same word line compose one or more physical programming units. In addition, a plurality of physical programming units can compose one physical unit (a physical block or a physical erasing unit). In this embodiment, the TLC (Triple Level Cell) NAND flash memory is taken as an example. That is to say, in the following embodiment, one memory cell capable of storing three bit values is used as one physical programming unit (i.e., in each programming operation, the data is programmed by applying a programming voltage one by one on the physical programming units). Here, each memory cell may be divided into a lower physical page, a middle physical page and an upper physical page, each of which is capable of storing one bit value.

In this embodiment, the memory cell is used as a minimum unit for writing (programming) data. The physical unit is a minimum unit for erasing (i.e., each physical unit includes a minimum number of memory cells to be erased together).

The following embodiments are provided with a TLC flash memory module as an example, in which a read voltage optimization operation in page-level is performed for a specific physical page of a specific word line in the TLC flash memory module (e.g., one of the lower physical page, the middle physical page and the upper physical page). A read voltage optimization method used by the read voltage optimization operation will also be described as follows. Nonetheless, the read voltage optimization operation in page-level and the read voltage optimization method are also applicable to other types of flash memory modules.

The storage controller 210 assigns a plurality of logical units for the rewritable non-volatile memory module 220. The host system 10 accesses user data stored in a plurality of physical units through the assigned logical units. Here, each of the logical units may be composed of one or more logical addresses. For example, the logical unit may be a logical block, a logical page, or a logical sector. One logical unit may be mapped to one or more physical units, where the physical unit may be one or more physical addresses, one or more physical sectors, one or more physical programming units, or one or more physical erasing units. In the present embodiment, the logical unit is a logical block, and the logical sub-unit is a logical page. Each logical unit includes a plurality of logical sub-units.

For instance, the storage controller 210 can create a logical to physical address mapping table and a physical to logical address mapping table for recording a mapping relation between the logical units (e.g., the logical blocks, the logical pages or the logical sectors) assigned to the rewritable non-volatile memory module 220 and the physical units (e.g., the physical erasing units, the physical programming units or the physical sectors). In other words, the storage controller 210 can search for the physical unit mapped to one logical unit by using the logical to physical address mapping table, and the storage controller 210 can search for the logical unit mapped to one physical unit by using the physical to logical address mapping table. Nonetheless, the technical concept for the mapping relation between the logical units and the physical units is a well-known technical means in the field and is not a technical solution to be described in the invention.

In this embodiment, the error checking and correcting circuit 214 is coupled to the processor 211 and configured to execute an error checking and correcting procedure to ensure correctness of data. Specifically, when the processor 211 receives the write command from the host system 10, the error checking and correcting circuit 214 generates an ECC (error correcting code) and/or an EDC (error detecting code) for data corresponding to the write command, and the processor 211 writes data corresponding to the write command and the corresponding ECC and/or the EDC into the rewritable non-volatile memory module 220. Then, when the processor 211 reads the data from the rewritable non-volatile memory module 220, the ECC and/or the EDC corresponding to the data are also read, and the error checking and correcting circuit 214 performs the error checking and correcting procedure on the read data based on the ECC and/or the EDC. In addition, after the error checking and correcting procedure is completed, if the read data is successfully decoded, the error checking and correcting circuit 214 can transmit an error bit count back to the processor 211.

In an embodiment, the storage controller 210 further includes a buffer memory 216 and a power management circuit 217. The buffer memory is coupled to the processor 211 and configured to temporarily store data and commands from the host system 10, data from the rewritable non-volatile memory module 220 or other system data for managing the storage device 20 so the processor 211 can rapidly access the data, the command or the system data from the buffer memory 216. The power management circuit 217 is coupled to the processor 211 and configured to control power of the storage device 20.

In this embodiment, a read voltage management circuit unit 215 includes a test code management circuit 2151 and a read voltage optimization circuit 2152. The read voltage management circuit unit 215 is configured to manage read voltages of the word lines. More specifically, at a specific time point, the processor 211 can select one word line (a.k.a. a target word line) among the word lines belonging to a plurality of physical units of the rewritable non-volatile memory module 220 and a specific physical page (a.k.a. a target physical page) of the target word line, and instructs the read voltage management circuit unit 215 to perform the read voltage optimization operation on the target physical page of the target word line. For instance, the processor 211 can select one target word line from all the word lines for the read voltage optimization operation at one of the following timing points: (1) when the storage device 20 is idle (i.e., when the storage device 20 is idle for more than a predetermined time threshold); (2) when the storage device is powered on; (3) when the error bit count of data read from one word line exceeds an error bit count threshold. Here, the processor 211 can select the word line with a poorer physical state (e.g., a word line with higher erase count, higher read count, longer stored time or higher error bit count) as the target word line.

In addition, the processor 211 can also select the target physical page of the target word line according to the error bit count transmitted from the error check and correction circuit 214. Specifically, when the error bit count of data read from a physical page of a word line exceeds the error bit count threshold, said word line is selected as the target word line and said physical page is selected as the target physical page. It should be noted that, the selected target word line is already stored with data, i.e., programmed with data. In addition, if the read voltage optimization operation for the target physical page of the target word line is completed and the corresponding optimized read voltage set is obtained, the read voltage management circuit unit 215 can record the optimized read voltage set corresponding to the target physical page of the target word line.

In an embodiment, the processor 211 may also select the target word line randomly, and then select one physical page from the physical pagers in the selected target word line as the target physical page according to a specific rule, so as to perform the read voltage optimization operation on the selected target physical page. The specific rule is, for example, based on a physical state of the physical page. For example, the physical page with a corresponding syndrome being poorer; the physical page with higher error bit count. In an embodiment, because a 3D flash memory is constructed in a stacked manner, different stack layers will differ from each other. Therefore, one of the physical pages in the consecutive word lines of each stacked layer may be assigned as the target physical page based on sections of the stacked layer. Whether the target physical page is selected from a start section, a middle section or an end section among the sections is not particularly limited by the invention. In an embodiment, the target physical page may also be selected in a random manner. In an embodiment, the processor 211 may also directly perform the read voltage optimization operation on all the physical pages of all the word lines in sequence.

The data reading method and the storage controller provided by the embodiments of the invention is described in detail below with reference to the drawings. In particular, details regarding how the read voltage management circuit unit 215 performs the read voltage optimization operation as well as functions of the test code management circuit 2151 and the read voltage optimization circuit 2152 are also described below.

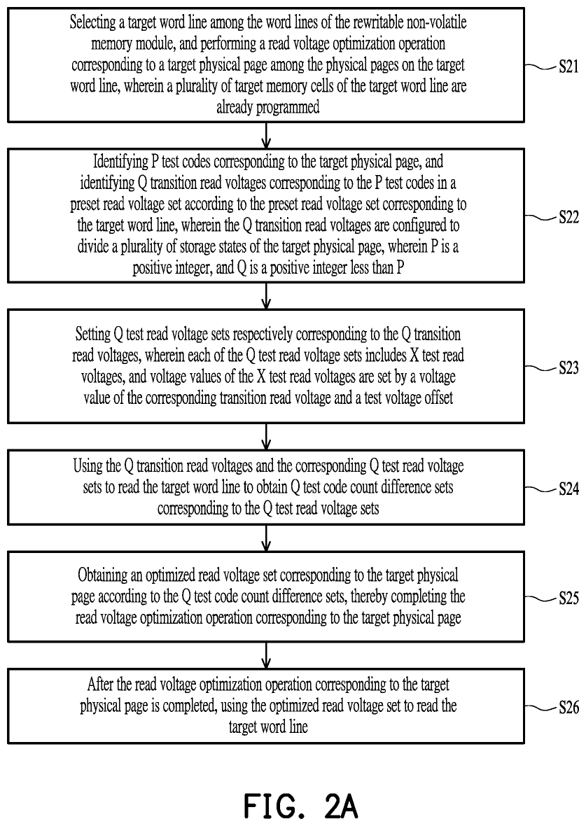

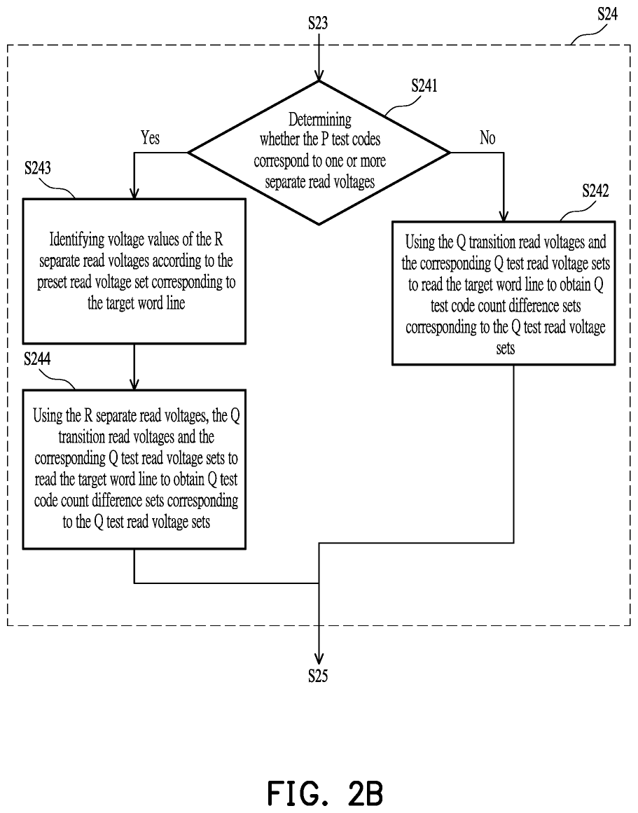

FIG. 2A is a flowchart illustrating a data reading method according to an embodiment of the invention. Referring to FIG. 1 and FIG. 2A together, in step S21, the processor 211 selects a target word line among the word lines of the rewritable non-volatile memory module 220, and performs a read voltage optimization operation corresponding to a target physical page among the physical pages on the target word line, wherein a plurality of target memory cells of the target word line are already programmed.

A selecting method for the target word line and the target physical page has been described above, and will not be repeated hereinafter. It should be noted that, the invention is not limited by the selecting method described above. In other words, if the processor 211 intends to perform the read voltage optimization operation in page-level on a specific physical page, that specific physical page may be regarded as the target physical page, and the word line to which the specific physical page belongs may be regarded as the target word line.

In this embodiment, as described above, the target word line is stored with data. Specifically, the memory cells of each of the word lines are configured to be programmed to store a bit value corresponding to one of a plurality of different gray codes, and a total number of the gray codes is N. N is a first predetermined positive integer greater than 2, and a value of N may be set in advance according to a type of the rewritable non-volatile memory module 220. For example, if the rewritable non-volatile memory module 220 is the MLC, N=4; if the rewritable non-volatile memory module 220 is the SLC, N=2; if the rewritable non-volatile memory module 220 is the QLC, N=16.

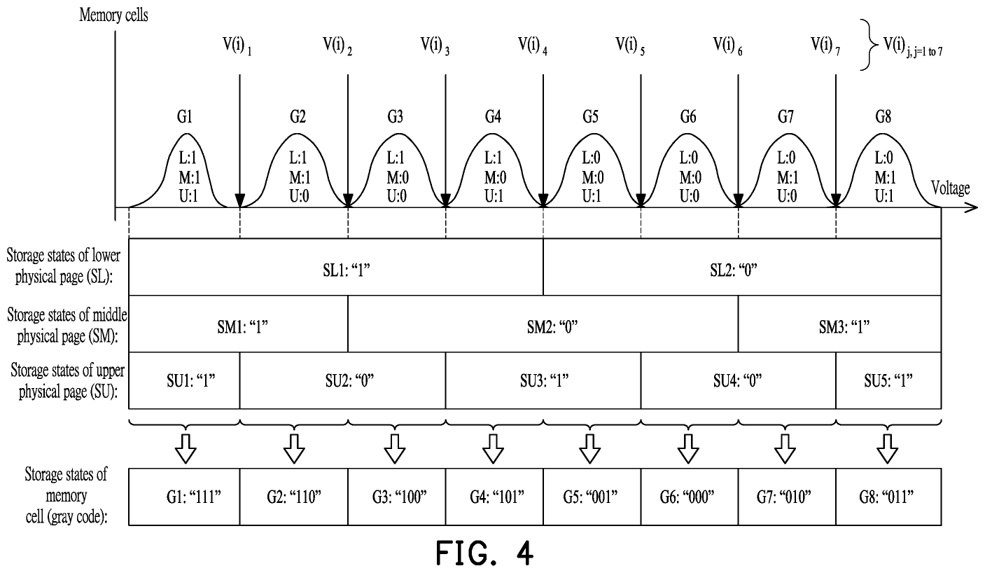

For descriptive convenience, the present embodiment takes the TLC flash memory module as an example, in which the memory cells of the target word line can store the bit values respectively corresponding to 8 gray codes (N=8). Details regarding the gray codes are described below with reference to FIG. 4.

FIG. 4 is a schematic diagram illustrating threshold voltage distributions of a plurality of memory cells corresponding to N gray codes read through a read voltage set and storage states of the corresponding physical page according to an embodiment of the invention. Since the present embodiment takes the rewritable non-volatile memory module 220 in a TLC NAND flash memory module as an example, N is equal to 8 (i.e., 2³). Each memory cell of the TLC NAND flash memory module has three physical pages for storing bit data, respectively, and each memory cell includes the lower physical page (L), the middle physical page (M) and the upper physical page (U), each of which is capable of storing one bit value. It is assumed that, the processor 211 reads a plurality of memory cells (a plurality of target memory cells) of the target word line of the TLC NAND flash memory module through a plurality of read voltages V(i)₁ to V(i)₇ in a read voltage set V(i), and accordingly identifies the different bit values stored by the memory cells (the bit values respectively corresponding to the different gray codes). According to the read voltages V(i)₁ to V(i)₇ in the read voltage set V(i) (e.g., a preset read voltage set with the corresponding i equal to 1), a gate voltage in each memory may be divided into 8 gray codes, such as “L:1 M:1 U:1”, “L:1 M:1 U:0”, “L:1 M:0 U:0”, “L:1 M:0 U:1”, “L:0 M:0 U:1”, “L:0 M:0 U:0”, “L:0 M:1 U:0” and “L:0 M:1 U:1” (“L:” indicates the bit value of the lower physical page; “M:” indicates the bit value of the middle physical page; “U:” indicates the bit value of the upper physical page). The eight gray codes may also be expressed by eight bit value combinations, including “111”, “110”, “100”, “101”, “001”, “000”, “010” and “011”. Here, an order of the bit values in each bit value combination is based on an order of the lower, middle and upper physical pages in that sequence. In other words, by applying the read voltages V(i)₁ to V(i)₇ with different voltage values in the read voltage set V(i) to one memory cell of the target word line, the processor 211 can determine the bit value stored by that memory cell (a.k.a. bit data or a read bit value) corresponding to one of the gray codes (“111”, “110”, “100”, “101”, “001”, “000”, “010” and “011”) according to whether a channel of that memory cell is turned on (i.e., using the first read voltage set V(i) to read the read bit value from the one memory of the target word line). It should be noted that, based on a number of the gray codes that can be included by the memory cell of the rewritable non-volatile memory module 220 (which is 8 in this example), the number of the read voltages in each read voltage set is the number of the gray codes minus one (which is 7 in this example, i.e., N−1=8−1=7).

More specifically, the gray code stored by one memory may be formed by storage states of the lower physical page (SL), storage states of the middle physical page (SM) and storage states of the upper physical page (SU) in that sequence (as shown by multiple arrows in FIG. 4).

In this embodiment, the read voltage V(i)₄ is configured to divide storage states SL1 (“1”) and SL2 (“0”) of the lower physical page; the read voltages V(i)₂ and V(i)₆ are configured to divide storage states SM1 (“1”), SM2 (“0”) and SM3 (“1”) of the middle physical page; the read voltages V(i)₁, V(i)₃, V(i)₅ and V(i)₇ are configured to divide storage states SU1 (“1”), SU2 (“0”), SU3 (“1”), SU4 (“0”) and SUS (“1”) of the upper physical page. The example above may also be regarded as to say that, the lower physical page has “one” transition read voltage, i.e., the read voltage V(i)₄; the middle physical page has “two” transition read voltages, i.e., the read voltages V(i)₂ and V(i)₆;

the upper physical page has “four” transition read voltages, i.e., the read voltages V(i)₁, V(i)₃, V(i)₅ and V(i)₇.

The processor 211 (or the read voltage management circuit unit 215) can use the transition read voltages corresponding to the lower physical page, the middle physical page and the upper physical page in the preset read voltage set to read the word line in sequence, so as to obtain the storage states of the lower physical page, the middle physical page and the upper physical page of the memory cells of the word lines and accordingly obtain the gray codes of the memory cells. For instance, it is assumed that the processor 211 (or the read voltage management circuit unit 215) uses the read voltage set V(i) to read the word lines to obtain the gray codes of the memory cells of the word lines. The processor 211 (or the read voltage management circuit unit 215) first identifies whether the storage states of all the lower physical pages of all the memory cells are the storage state SL1 or the storage state SL2 by using the read voltage V(i)₄; then, the processor 211 (or the read voltage management circuit unit 215) then identifies whether the storage states of all the middle physical pages of all the memory cells are the storage state SM1, the storage state SM2 or the storage state SM3 by using the read voltages V(i)₂ and V(i)₆; then, the processor 211 (or the read voltage management circuit unit 215) then identifies whether the storage states of all the upper physical pages of all the memory cells are the storage state SU1, the storage state SU2, the storage state SU3, the storage state SU4 or the storage state SUS by using the read voltages V(i)₁, V(i)₃, V(i)₅ and V(i)₇. Accordingly, the processor 211 (or the read voltage management circuit unit 215) can identify the storage states of the lower physical pages, the middle physical pages and the upper physical pages of all the memory cells, and thereby identify the gray codes stored by all the memory cells.

In addition, the rewritable non-volatile memory module 220 with the characteristics of having the foregoing physical pages and the corresponding number of the transition read voltages may also be regarded as a rewritable non-volatile memory module 220 (the TLC NAND flash memory module) having a first read voltage mode (1/2/4). The so-called “1/2/4” corresponds to the total number of the transition read voltages respectively included by “the lower physical page/the middle physical page/the upper physical page”.

In order to facilitate the description of the technical solution provided by the invention, most of the following embodiments are described with the rewritable non-volatile memory modules 220 (the TLC NAND flash memory module) having the first read voltage mode (1/2/4) as an example. Nevertheless, the data reading method and the storage controller provided by the invention is also applicable to the rewritable non-volatile memory module 220 having other read voltage modes.

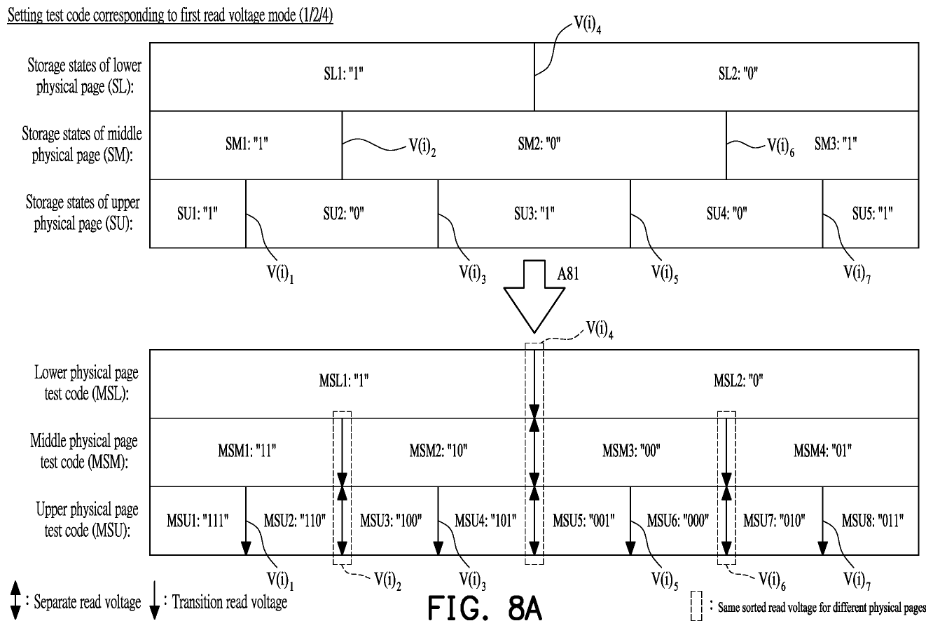

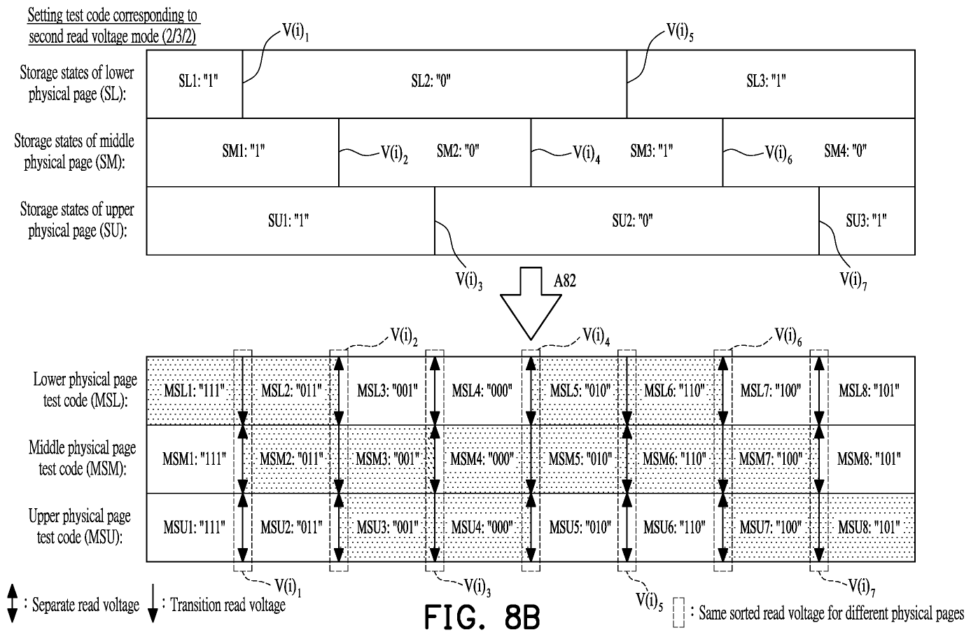

For example, in an embodiment, as shown by an upper portion of FIG. 8B, for the rewritable non-volatile memory module 220 (the TLC NAND flash memory module) in a second read voltage mode (2/3/2), the read voltages V(i)₁ and V(i)₅ are configured to divide storage states SL1 (“1”), SL2 (“0”) and SL3 (“1”) of the lower physical page; the read voltages V(i)₂, V(i)₄ and V(i)₆ are configured to divide storage states SM1 (“1”), SM2 (“0”), SM3 (“1”) and SM4 (“0”) of the middle physical page; the read voltages V(i)₃ and V(i)₇ are configured to divide the storage states SU1 (“1”), SU2 (“0”) and SU3 (“1”) of the upper physical page. The example above may also be regarded as to say that, among the memory cells of the rewritable non-volatile memory module 220 (the TLC NAND flash memory module) in the second read voltage mode (2/3/2), the lower physical page has “two” transition read voltages, i.e., the read voltages V(i)₁ and V(i)₅; the middle physical page has “three” transition read voltages, i.e., the read voltages V(i)₂, V(i)₄ and V(i)₆; the upper physical page has “two” transition read voltages, i.e., the read voltages V(i)₃ and V(i)₇.

In this embodiment, the threshold voltage distributions of the physical pages of the memory cells of the word line may have an offset as compared to a preset threshold voltage distribution. Due to the offset of the transition read voltage, preset transition read voltages originally corresponding to preset threshold voltages of the physical pages are no longer suitable for dividing the storage states of the corresponding physical pages. The processor 211 needs to additionally find one or more better transition read voltages (a.k.a. optimized read voltages) corresponding to the target physical page to make the one or more optimized read voltages close to an intersection between two adjacent threshold voltage distributions of the corresponding target physical page. Then, the found optimized read voltages may be used to replace the original preset transition read voltages and to form the optimized read voltage set corresponding to the target physical page.

Returning to FIG. 2A, after receiving the instruction from the processor 211, the read voltage management circuit unit 215 starts to execute the read voltage optimization operation corresponding to the target physical page. The read voltage optimization operation includes steps S22 to S25.

In the step S22, the read voltage management circuit unit 215 identifies P test codes corresponding to the target physical page, identifies Q transition read voltages corresponding to the P test codes in a preset read voltage set according to the preset read voltage set corresponding to the target word line, wherein the Q transition read voltages are configured to divide a plurality of storage states of the target physical page, wherein P is used to represent a total number of test codes corresponding to the target physical page, and P is a positive integer greater than one, wherein Q is used to represent a total number of one or more transition read voltages corresponding to the target physical page, and Q is a positive integer.

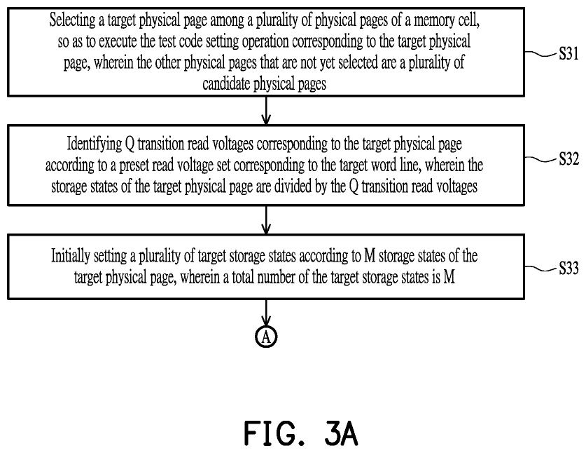

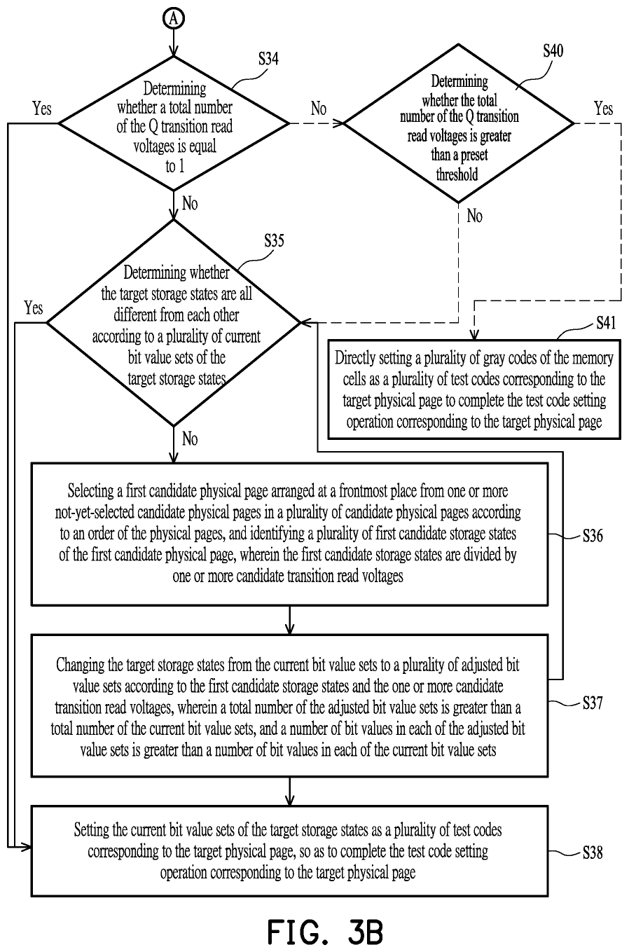

Specifically, in this embodiment, for the physical pages (the lower physical page, the middle physical page and the upper physical page) of the memory cells of the read voltage management circuit unit 220, the read voltage management circuit unit 215 (or the test code management circuit 2151) can execute a plurality of test code setting operations corresponding to the physical pages by the test code setting method, so as to obtain a plurality of test codes of each physical page among the physical pages. The read voltage management circuit unit 215 (or the test code management circuit 2151) can record the test codes of each physical page among the physical pages to a test code table adapted to the read voltage management circuit unit 220. The test code setting method provided by the present embodiment is described below with reference to FIGS. 3A-3B.

FIGS. 3A-3B are flowcharts illustrating a test code setting method according to an embodiment of the invention. Referring to FIG. 3A, in step S31, the test code management circuit 2151 selects a target physical page among a plurality of physical pages of a memory cell, so as to execute the test code setting operation corresponding to the target physical page, wherein the other physical pages that are not yet selected are a plurality of candidate physical pages. For instance, it is assumed that the test code management circuit 2151 intends to set the corresponding test codes for the lower physical page among the physical pages (the lower physical page, the middle physical page and the upper physical page) of the memory cells of the rewritable non-volatile memory module 220. In this case, the lower physical page is the selected target physical page, and the middle physical page and the upper physical page are the candidate physical pages.

Next, in step S32, the test code management circuit 2151 identifies Q transition read voltages corresponding to the target physical page according to a preset read voltage set corresponding to the target word line, wherein the storage states of the target physical page are divided by the Q transition read voltages. For example, with respect to the rewritable non-volatile memory module 220 in the first read voltage mode (1/2/4), if the target physical page is the lower physical page, the test code management circuit 2151 can identify one transition read voltage V(1)₄ corresponding to the lower physical page (Q is equal to 1) according to a preset read voltage set V(1); if the target physical page is the middle physical page, the test code management circuit 2151 can identify two transition read voltages V(1)₂ and V(1)₆ corresponding to the middle physical page (Q is equal to 2) according to the preset read voltage set V(1); if the target physical page is the upper physical page, the test code management circuit 2151 can identify four transition read voltages V(1)₁, V(1)₃, V(1)₅ and V(1)₇ corresponding to the upper physical page (Q is equal to 4) according to the preset read voltage set V(1).

Next, in step S33, the test code management circuit 2151 initially sets a plurality of target storage states according to M storage states of the target physical page, wherein a total number of the target storage states is M. For instance, it is assumed that, for the rewritable non-volatile memory module 220 in the first read voltage mode (1/2/4), if the target physical page is the lower physical page, said M is 2 and the target storage states are the storage state SL1 and the storage state SL2; if the target physical page is the middle physical page, said M is 3 and the target storage states are the storage state SM1, the storage state SM2 and the storage state SM3; if the target physical page is the upper physical page, said M is 5 and the target storage states are the storage state SU1, the storage state SU2, the storage state SU3, the storage state SU4 and the storage state SUS.

Next, referring to FIG. 3B, in step S34 (via the node A), the test code management circuit 2151 determines whether a total number of the Q transition read voltages is equal to 1. Here, in response to determining that the total number of the Q transition read voltages is equal to 1, step S38 is executed; in response to determining that the total number of the Q transition read voltages is not equal to 1, step S35 is executed.

It should be noted that, in an embodiment, in response to determining that the total number of the Q transition read voltages is not equal to 1, the process does not proceed to step S35 but proceeds to step S40. In addition, in an embodiment, step S34 may be omitted (i.e., step S35 may be directly executed after the step S33).

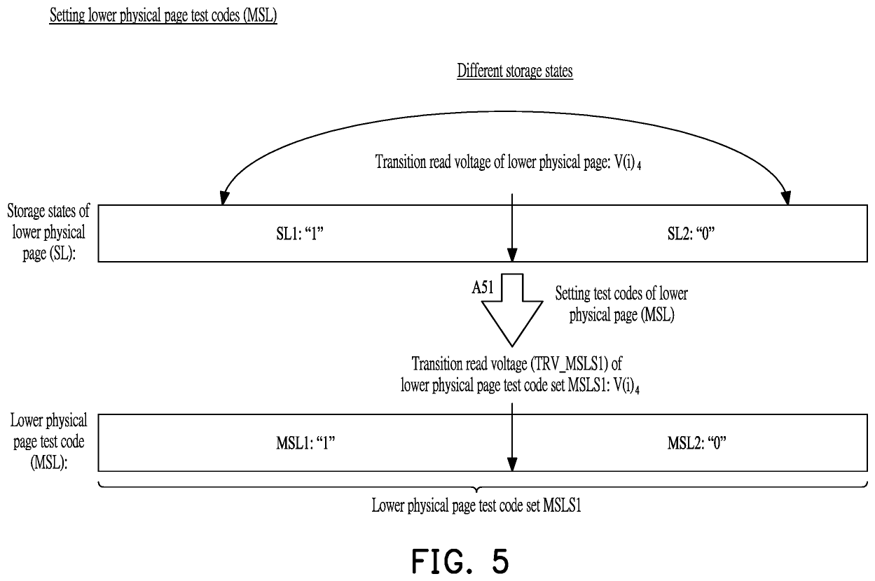

In step S38, the test code management circuit 2151 sets the current bit value sets of the target storage states as a plurality of test codes corresponding to the target physical page, so as to complete the test code setting operation corresponding to the target physical page. The test code setting operation for the target physical page being the lower physical page is described below with reference to FIG. 5.

FIG. 5 is a schematic diagram for setting lower physical page test codes according to an embodiment of the invention. Referring to FIG. 5, for instance, it is assumed that the selected target physical page is the lower physical page. The test code management circuit 2151 executes the test code setting operation corresponding to the lower physical page. Here, the middle physical page and the upper physical page are regarded as the candidate physical pages (S31). Next, the test code management circuit 2151 identifies one transition read voltage V(i)₄ of the lower physical page (Q=1) according to the preset read voltage V(i)₁ (S32). As shown by FIG. 5, the transition read voltage V(i)₄ is configured to divide two storage states SL1 and SL2 of the lower physical page (M=2). Next, the test code management circuit 2151 initially sets a plurality of target storage states according to the two storage states of the lower physical page (i.e., the current target storage states are the storage state SL1 (“1”) and the storage state SL2 (“0”)) (S33).

Next, the test code management circuit 2151 determines that the total number of the transition read voltages (Q) is equal to 1 (step S34→Yes), and the test code management circuit 2151 sets the current bit value sets (i.e., “1” and “0”) of the target storage states SL1 and SL2 as the test codes corresponding to the target physical page, so as to complete the test code setting operation corresponding to the target physical page (S38). In other words, as shown by an arrow A51 in FIG. 5, in response to determining that the total number of the transition read voltage of the lower physical page is equal to 1, the test code management circuit 2151 starts to set the test codes of lower physical page (a.k.a. a minimum separate code MSL of the lower physical page). Specifically, the test code management circuit 2151 uses the current storage state SL1 (“1”) and the storage state SL2 (“0”) of the lower physical page as the test codes of the lower physical page. In this example, the set test codes of the lower physical page include a test code MSL1 having the bit value set “1” and a test code MSL2 having the bit value set “0”.

As described above, in an embodiment, step S34 may be omitted, and the process proceeds to step S35. In the example of FIG. 5, the test code management circuit 2151 determines that the target storage states SL1 and SL2 of the lower physical pages are all different from each other (step 35→Yes), and the test code management circuit 2151 then executes step S38 to set the test codes MSL1 and MSL2 of the lower physical page according to the target storage states SL1 and SL2, so as to complete the test code setting operation corresponding to the target physical page.

In this embodiment, the test code MSL1 and the test code MSL2 can compose a lower physical page test code set MSLS1. In other words, two adjacent test codes can compose one test code set, and the composed test code set corresponds to one transition read voltage. For example, the lower physical page test code set MSLS1 corresponds to a transition read voltage TRV_MSLS1, V(i)₄.

In step S35, the test code management circuit 2151 determines whether the target storage states are all different from each other according to a plurality of current bit value sets of the target storage states. Here, in response to determining that the target storage states are all different from each other, step S38 is executed; in response to determining that the target storage states are not all different from each other, step S36 is executed. For instance, it is assumed that the target physical page is the lower physical page, and the current bit value sets of the target storage state SL1 and the target storage state SL2 are respectively the bit value set “1” and the bit value set “0” different from each other. In this example, the test code management circuit 2151 determines that the target storage state SL1 and the target storage state SL2 are all different from each other.

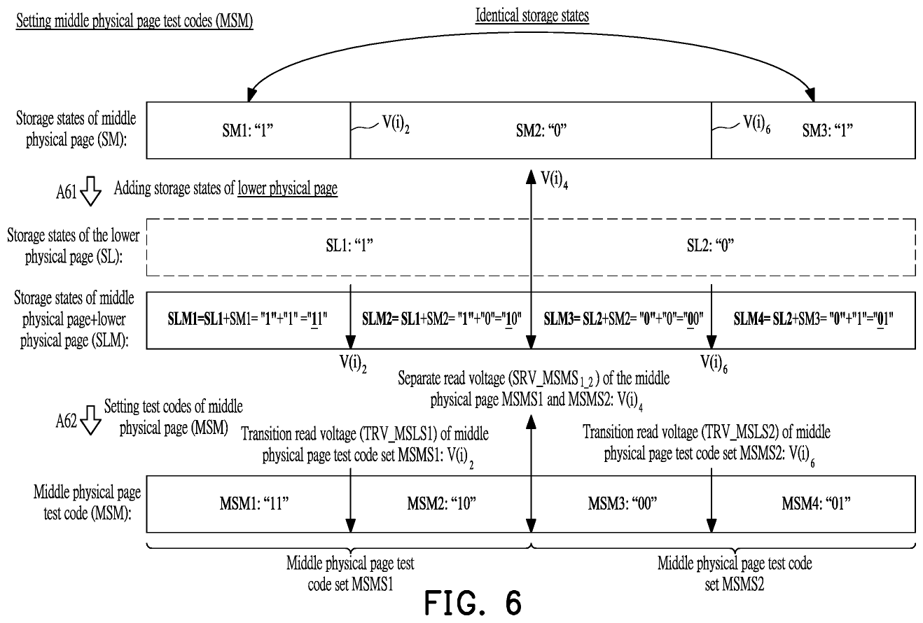

In step S36, the test code management circuit 2151 selects a first candidate physical page arranged at a frontmost place from one or more not-yet-selected candidate physical pages in a plurality of candidate physical pages according to an order of the physical pages, and identifies a plurality of first candidate storage states of the first candidate physical page, wherein the first candidate storage states are divided by one or more candidate transition read voltages. After selecting the first candidate physical page and identifying the first candidate storage states of the first candidate physical page, step S37 is executed. In step S37, the test code management circuit 2151 changes the target storage states from the current bit value sets to a plurality of adjusted bit value sets according to the first candidate storage states and the one or more candidate transition read voltages, wherein a total number of the adjusted bit value sets is greater than a total number of the current bit value sets, and a number of bit values in each of the adjusted bit value sets is greater than a number of bit values in each of the current bit value sets. Details regarding steps S36 and S37 are further described below with reference to FIG. 6.

FIG. 6 is a schematic diagram for setting middle physical page test codes according to an embodiment of the invention. Referring to FIG. 6, for instance, it is assumed that the selected target physical page is the middle physical page. The test code management circuit 2151 executes the test code setting operation corresponding to the middle physical page. Here, the lower physical page and the upper physical page are regarded as the candidate physical pages (S31). Next, the test code management circuit 2151 identifies two transition read voltages V(i)₂ and V(i)₆ (Q=2) according to the preset read voltage V(i)₁ (S32). As shown by FIG. 6, the transition read voltages V(i)₂ and V(i)₆ are configured to divide three storage states SM1, SM2 and SM3 of the middle physical page (M=3). Next, the test code management circuit 2151 initially sets a plurality of target storage states SM1, SM2 and SM3 according to the three storage states SM1, SM2 and SM3 of the middle physical page (i.e., the current target storage states are the storage state SM1 (“1”), the storage state SM2 (“0”) and the storage state SM2 (“1”)) (S33).

Next, the test code management circuit 2151 determines that the total number of the transition read voltages V(i)₂ and V(i)₆ of the middle physical page is not equal to 1 (Q=2) (step S34→No), and the test code management circuit 2151 then determines that the target storage states SM1, SM2 and SM3 are not all different from each other (step S35→No) (e.g., the target storage state SM1 is identical to the target storage state SM3). Then, the process proceeds to step S36.

In step S36, the test code management circuit 2151 selects the first candidate physical page arranged at the frontmost place from one or more not-yet-selected candidate physical pages in the candidate physical pages according to the order of the physical pages. In this example, the candidate physical pages are the lower physical page and the upper physical page, wherein the lower physical page is arranged in front of the upper physical page. In other words, the test code management circuit 2151 will select the lower physical page as the first candidate physical page, and identify the storage states SL1 and SL2 of the lower physical page as the first candidate storage states. Here, the first candidate storage states SL1 and SL2 are divided by the transition read voltage V(i)₄. That is to say, the first candidate physical page corresponds to one candidate transition read voltage V(i)₄.

In this embodiment, during the process of executing step S37, the test code management circuit 2151 changes the target storage states from the current bit value sets to the adjusted bit value sets by adding the first candidate storage states of the first candidate physical page to the target storage states. For instance, according to the voltage value of the transition read voltage V(i)₂ corresponding to the target storage states SM1 and SM2 and the voltage value of the transition read voltage V(i)₄ of the lower physical page, the test code management circuit 2151 can identify that: among all the memory cells of the target word line, the storage states of the lower physical pages of a plurality of memory cells having the voltage value of the threshold voltage being less than the voltage value of the transition read voltage V(i)₄ are the storage state SL1, the storage states of a part of said memory cells with the storage state SL1 having the voltage value of the threshold voltage being less than the voltage value of the transition read voltage V(i)₂ are the storage state SM1, and the storage states of the other memory cells (i.e., the remaining part of said memory cells having the voltage value of the threshold voltage not being less than the voltage value of the transition read voltage V(i)₂ among the memory cells) are the storage state SM2. In addition, according to the voltage value of the transition read voltage V(i)₆ corresponding to the target storage states SM2 and SM3 and the voltage value of the transition read voltage V(i)₄ of the lower physical page, the test code management circuit 2151 can identify that: among all the memory cells of the target word line, the storage states of the lower physical pages of a plurality of memory cells having the voltage value of the threshold voltage not being less than the voltage value of the transition read voltage V(i)₄ are the storage state SL2, storage states of a part of said memory cells with the storage state SL2 having the voltage value of the threshold voltage being less than the voltage value of the transition read voltage V(i)₆ are the storage state SM2, and the storage states of the other memory cells (i.e., the remaining part of memory cells having the voltage value of the threshold voltage not being less than the voltage value of the transition read voltage V(i)₆ among the memory cells) are the storage state SM3.

In brief, for the memory cells having the threshold voltage being less than the transition read voltage V(i)₄ and less than the transition read voltage V(i)₂, the bit value set of the storage state may be obtained by adding the storage state SM1 (“1”) of the middle physical page to the storage state SL1 (“1”) of the lower physical page, i.e., the obtained bit value set of the storage state is “11” (a.k.a. the adjusted bit value set); for the memory cells having the threshold voltage being less than the transition read voltage

V(i)₄ and not being less than the transition read voltage V(i)₂, the bit value set of the storage state may be obtained by adding the storage state SM2 (“0”) of the middle page to the storage state SL1 (“1”) of the lower physical page, i.e., the obtained bit value set of the storage state is “10”; for the memory cells having the threshold voltage not being less than the transition read voltage V(i)₄ and being less than the transition read voltage

V(i)₆, the bit value set of the storage state may be obtained by adding the storage state SM2 (“0”) of the middle physical page to the storage state SL2 (“0”) of the lower physical page, i.e., the obtained bit value set of the storage state is “00”; for the memory cells having the threshold voltage not being less than the transition read voltage

V(i)₄ and not being less than the transition read voltage V(i)₆, the bit value set of the storage state may be obtained by adding the storage state SM3 (“1”) of the middle physical page to the storage state SL2 (“0”) of the lower physical page, i.e., the obtained bit value set of the storage state is “01”.

In other words, by adding the storage states SL1 and SL2 of the lower physical page to the current target storage states SM1, SM2 and SM3 according to the voltage value of the transition read voltage of the lower physical page (e.g., as shown by an arrow A61), the test code management circuit 2151 can change the target storage states SM1, SM2 and SM3 respectively having the current bit value sets “1”, “0” and “1” to the target storage states SLM1, SLM2, SLM3 and SLM4 respectively having the adjusted bit value sets “11”, “10”, “00” and “01”. Here, a total number of the adjusted bit value sets 11″, “10”, “00” and “01” (i.e., 4) is greater than a total number of the bit value sets “1”, “0” and “1” (i.e., 3), and a number of bit values in each of the adjusted bit value sets “11”, “10”, “00” and “01” (i.e., 2) is greater than a number of bit values of each of the bit value sets “1”, “0” and “1” (i.e., 1).

After obtaining the changed target storage states SLM1, SLM2, SLM3 and SLM4 (the current bit value sets of the target storage states SLM1, SLM2, SLM3 and SLM4 are “11”, “10”, “00” and “01”), the process proceeds to step S35. At this time, the test code management circuit 2151 determines that the target storage states SLM1, SLM2, SLM3 and SLM4 are all different from each other (step S35→Yes). Next, in step S38, the test code management circuit 2151 sets the bit value sets “11”, “10”, “00” and “01” of the target storage states SLM1, SLM2, SLM3 and SLM4 as a plurality of test codes MSM1, MSM2, MSM3 and MSM4 corresponding to the middle physical page (as shown by an arrow A62), so as to complete the test code setting operation corresponding to the middle physical page. In this example, the test codes MSM1 and MSM2 of the middle physical page compose a middle physical page test code set MSMS1, and the composed middle physical page test code set MSMS1 corresponds to one transition read voltage TRV_MSMS1, V(i)₂; the test codes MSM3 and MSM4 of the middle physical page compose a middle physical page test code set MSMS2, and the composed middle physical page test code set MSMS2 corresponds to one transition read voltage TRV_MSMS2, V(i)₆. In addition, the memory cells belonging to the two adjacent middle physical page test code sets MSMS1 and MSMS2 may be divided according to a first candidate transition read voltage V(i)₄, and the test code management circuit 2151 can identify the first candidate transition read voltage V(i)₄ as a separate read voltage SRV_MSMS_{1_2}, V(i)₄ of the middle physical page test code sets MSMS1 and MSMS2. In other words, the test codes MSM1, MSM2, MSM3 and MSM4 corresponding to the target physical page (the middle physical page) can correspond to the separate read voltage SRV_MSMS_{1_2}, V(i)₄.

It should be noted that, in this embodiment, the separate read voltage corresponding to the test codes of the target physical page is marked by a two-headed arrow in the drawing, and the target physical page corresponding to the test codes of the target physical page is marked by a one-head arrow in the drawing.

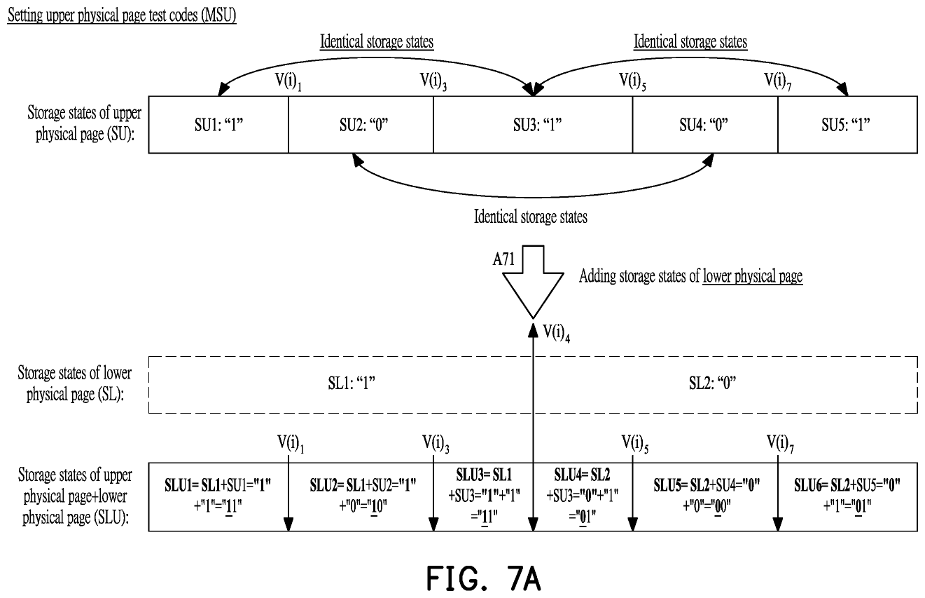

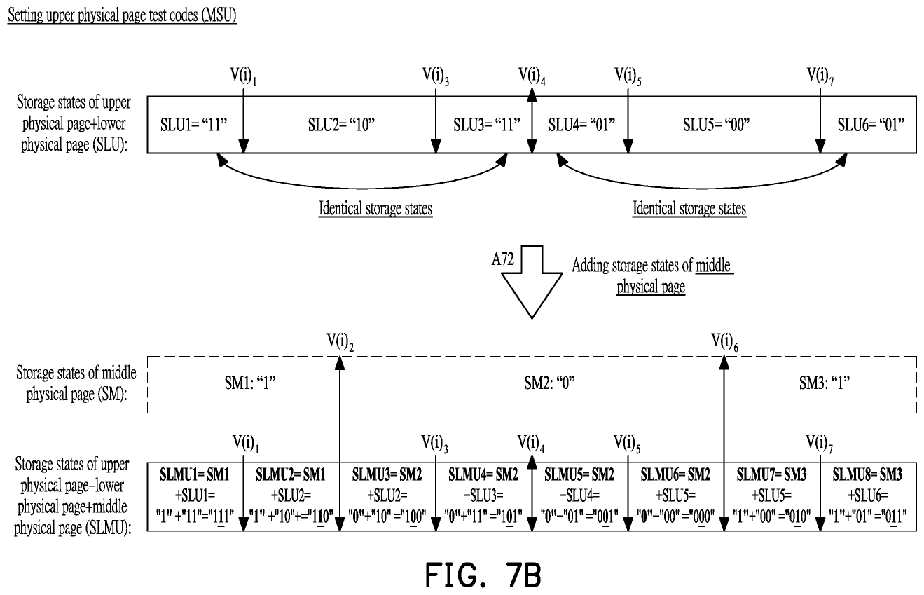

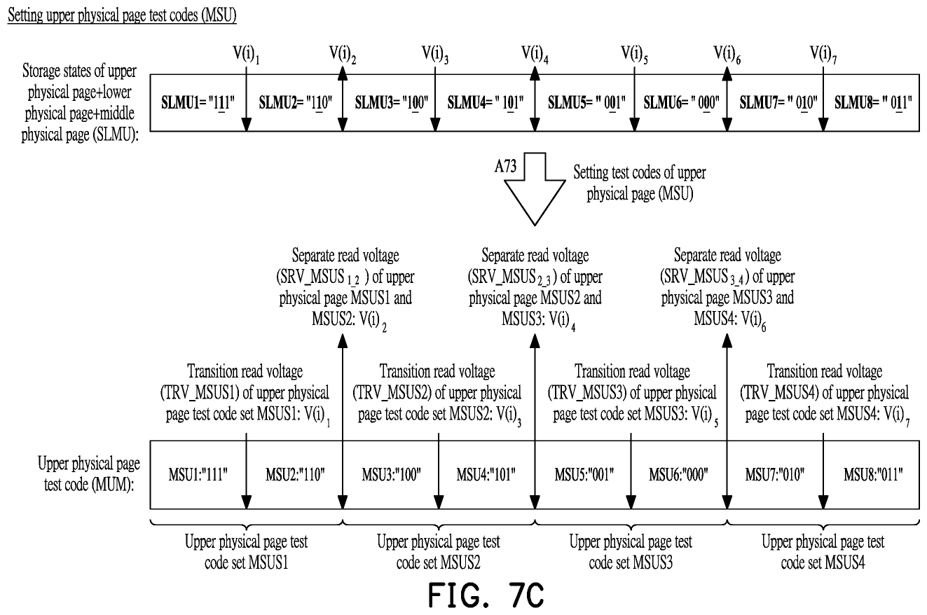

FIG. 7A, FIG. 7B and FIG. 7C are schematic diagrams for setting upper physical page test codes according to an embodiment of the invention. Referring to FIG. 7A, for instance, it is assumed that the selected target physical page is the upper physical page. The test code management circuit 2151 executes the test code setting operation corresponding to the upper physical page. Here, the lower physical page and the middle physical page are regarded as the candidate physical pages (S31). Next, the test code management circuit 2151 identifies four transition read voltages V(i)₁, V(i)₃, V(i)₅ and V(i)₇ of the upper physical page (Q=4) according to the preset read voltage V(i)₁ (S32). As shown by FIG. 7A, the transition read voltages V(i)₁, V(i)₃, V(i)₅ and V(i)₇ are configured to divide five storage states SU1, SU2, SU3, SU4 and SUS of the upper physical page (M=5). Next, the test code management circuit 2151 initially sets target storage state SU1, SU2, SU3, SU4 and SUS according to the five storage states SU1, SU2, SU3, SU4 and SUS (i.e., the current target storage states are the storage state SU1 (“1”), the storage state SU2 (“0”), the storage state SU3 (“1”), the storage state SU4 (“0”) and the storage state SUS (“1”)) (S33).

Next, the test code management circuit 2151 determines that the total number of the transition read voltages V(i)₁, V(i)₃, V(i)₅ and V(i)₇ of the upper physical page is not equal to 1 (4≠1) (step S34→No), and the test code management circuit 2151 then determines that the target storage states SU1, SU2, SU3, SU4 and SUS are not all different from each other (step S35→No) (e.g., the target storage state SU1 is identical to the target storage states SU3 and SUS, and the target storage state SU2 is identical to the target storage state SU4). Then, the process proceeds to step S36.

In step S36, the test code management circuit 2151 selects the first candidate physical page arranged at the frontmost place from one or more not-yet-selected candidate physical pages in the candidate physical pages according to the order of the physical pages. In this example, the candidate physical pages are the lower physical page and the middle physical page, wherein the lower physical page is arranged in front of the middle physical page. In other words, the test code management circuit 2151 will select the lower physical page as the first candidate physical page, and identify the storage states SL1 and SL2 of the lower physical page as the first candidate storage states. Here, the first candidate storage states SL1 and SL2 are divided by the transition read voltage V(i)₄. That is to say, the first candidate physical page corresponds to one first candidate transition read voltage V(i)₄.

In this embodiment, during the process of executing step S37, the test code management circuit 2151 adds the first candidate storage states SL1 and SL2 of the first candidate physical page to the current target storage states SU1, SU2, SU3, SU4 and SUS (as shown by an arrow A71), so as to obtain changed target storage states SLU1, SLU2, SLU3, SLU4, SLUS and SLU6 having the bit value sets “11”, “10”, “11”, “01”, “00” and “01”. It should noted that, the current target storage states SLU1, SLU2, SLU3, SLU4, SLUS and SLU6 correspond to one separate read voltage V(i)₄ and four transition read voltages V(i)₁, V(i)₃, V(i)₅ and V(i)₇.

With reference to FIG. 7B, after obtaining the changed target storage states SLU1, SLU2, SLU3, SLU4, SLUS and SLU6 (the current bit value sets of the target storage states SLU1, SLU2, SLU3, SLU4, SLUS and SLU6 are “11”, “10”, “11”, “01”, “00” and “01”), the process proceeds to step S35. At this time, the test code management circuit 2151 determines that the target storage states SLU1, SLU2, SLU3, SLU4, SLUS and SLU6 are not all different from each other (step S35→No) (e.g., the target storage state SLU1 is identical to the target storage state SLU3, and the target storage state SLU4 is identical to the target storage state SLU6), and the process again proceeds to step S36.

In step S36, the test code management circuit 2151 selects the first candidate physical page arranged at the frontmost place from one or more not-yet-selected candidate physical pages in the candidate physical pages according to the order of the physical pages. At this time, the not-yet-selected candidate physical pages remained in the candidate physical pages are the middle physical pages (the lower physical page in the candidate physical pages has been selected in the previously executed step S36), and the middle physical page is the first candidate physical page arranged at the foremost place. In other words, the test code management circuit 2151 will select the middle physical page as the first candidate physical page, and identify the storage states SM1, SM2 and SM3 of the middle physical page as the first candidate storage states. Here, the first candidate storage states SM1, SM2 and SM3 are divided by the transition read voltages V(i)₂ and V(i)₆. That is to say, the first candidate physical page corresponds to two first candidate transition read voltages V(i)₂ and V(i)₆.

In this embodiment, during the process of executing step S37, the test code management circuit 2151 adds the first candidate storage states SM1, SM2 and SM3 of the first candidate physical page (the middle physical page) to the current target storage states SLU1, SLU2, SLU3, SLU4, SLUS and SLU6 (as shown by an arrow A72), so as to obtain changed target storage states SLMU1, SLMU2, SLMU3, SLMU4, SLMUS, SLMU6, SLMU7 and SLMU8 having the bit value sets “111”, “110”, “100”, “101”, “001”, “000”, “010” and “011”. It should noted that, the current target storage states SLMU1, SLMU2, SLMU3, SLMU4, SLMUS, SLMU6, SLMU7 and SLMU8 correspond to three separate read voltages V(i)₂, V(i)₄ and V(i)₆ and four transition read voltages V(i)₁, V(i)₃, V(i)₅ and V(i)₇.

After obtaining the changed target storage states SLMU1, SLMU2, SLMU3, SLMU4, SLMUS, SLMU6, SLMU7 and SLMU8 (the current bit value sets of the target storage states SLMU1, SLMU2, SLMU3, SLMU4, SLMUS, SLMU6, SLMU7 and SLMU8 are “111”, “110”, “100”, “101”, “001”, “000”, “010” and “011”), the process again proceeds to step S35.

At this time, the test code management circuit 2151 determines that the target storage states SLMU1, SLMU2, SLMU3, SLMU4, SLMUS, SLMU6, SLMU7 and SLMU8 are all different from each other (step S35→Yes), and the process proceeds to the step S38.

With reference to FIG. 7C, next, in step S38, the test code management circuit 2151 sets the bit value sets “111”, “110”, “100”, “101”, “001”, “000”, “010” and “011” of the target storage states SLMU1, SLMU2, SLMU3, SLMU4, SLMUS, SLMU6, SLMU7 and SLMU8 as a plurality of test codes MSU1, MSU2, MSU3, MSU4, MSUS, MSU6, MSU7 and MSU8 corresponding to the upper physical page (as shown by an arrow A73), so as to complete the test code setting operation corresponding to the upper physical page.

In this example, the test codes MSU1 and MSU2 of the upper physical page compose an upper physical page test code set MSUS1, and the composed upper physical page test code set MSUS1 corresponds to one transition read voltage TRV_MSUS1, V(i)ᵢ; the test codes MSU3 and MSU4 of the upper physical page compose an upper physical page test code set MSUS2, and the composed upper physical page test code set MSUS2 corresponds to one transition read voltage TRV_MSUS2, V(i)₃; the test codes MSUS and MSU6 of the upper physical page compose an upper physical page test code set MSUS3, and the composed upper physical page test code set MSUS3 corresponds to one transition read voltage TRV_MSUS3, V(i)₅; the test codes MSU7 and MSU8 of the upper physical page compose an upper physical page test code set MSUS4, and the composed upper physical page test code set MSUS4 corresponds to one transition read voltage TRV_MSUS4, V(i)₇.

In addition, the memory cells belonging to the two adjacent upper physical page test code sets MSUS1 and MSUS2 may be divided according to the first candidate transition read voltage V(i)₂, and the test code management circuit 2151 can identify the first candidate transition read voltage V(i)₂ as a separate read voltage SRV_MSUS_{1_2}, V(i)₂ of the upper physical page test code sets MSUS1 and MSUS2. In other words, the test codes MSU1, MSU2, MSU3 and MSU4 corresponding to the target physical page (the upper physical page) can correspond to the separate read voltage SRV_MSUS_{1_2}, V(i)₂.

The memory cells belonging to the two adjacent upper physical page test code sets MSUS3 and MSUS4 may be divided according to the first candidate transition read voltage V(i)₆, and the test code management circuit 2151 can identify the first candidate transition read voltage V(i)₆ as a separate read voltage SRV MSUS_{3_4}, V(i)₆ of the upper physical page test code sets MSUS3 and MSUS4. In other words, the test codes MSUS, MSU6, MSU7 and MSU8 corresponding to the target physical page (the upper physical page) can correspond to the separate read voltage SRV_MSUS_{3_4}, V(i)₆.

The memory cells belonging to the two adjacent upper physical page test code sets MSUS2 and MSUS3 may be divided according to the first candidate transition read voltage V(i)₄ of the previous time (FIG. 7A), and the test code management circuit 2151 can identify the first candidate transition read voltage V(i)₂ as a separate read voltage SRV_MSUS_{2_3}, V(i)₄ of the upper physical page test code sets MSUS2 and MSUS3. In other words, the test codes MSU3, MSU4, MSUS and MSU6 corresponding to the target physical page (the upper physical page) can correspond to the separate read voltage SRV_MSUS_{2_3}, V(i)₄.

FIG. 8A is a schematic diagram for setting a test code corresponding to a first read voltage mode according to an embodiment of the invention. FIG. 8B is a schematic diagram for setting a test code corresponding to a second read voltage mode according to an embodiment of the invention.

With reference to FIG. 8A, after the test code setting operation is executed for all the physical pages of the rewritable non-volatile memory module 220 in the first read voltage mode (1/2/4), as shown by an arrow A81, the test code management circuit 2151 can obtain and record: two test codes MSL1 and MSL2 corresponding to the lower physical page, where the two test codes MSL1 and MSL2 correspond to the transition read voltage V(i)₄; four test codes MSM1, MSM2, MSM3 and MSM4 corresponding to the middle physical page, where the four test codes MSM1, MSM2, MSM3 and MSM4 correspond to the transition read voltages V(i)₂ and V(i)₆ and the separate read voltage V(i)₄; eight test codes MSU1, MSU2, MSU3, MSU4, MSUS, MSU6, MSU7 and MSU8 corresponding to the upper physical page, and the eight test codes MSU1, MSU2, MSU3, MSU4, MSUS, MSU6, MSU7 and MSU8 correspond to the transition read voltages V(i)₁, V(i)₃, V(i)₅, V(i)₇ and the separate read voltages V(i)₄, V(i)₂ and V(i)₆. It should be noted that, after fixing (not adjusting) the applied separate read voltage of the corresponding physical page, a total number of the memory cells respectively corresponding to the test codes MSL1 and MSL2 may be changed by adjusting the applied transition read voltage V(i)₄; a total number of the memory cells respectively corresponding to the test codes MSM1 and MSM2 may be changed by adjusting the applied transition read voltage V(i)₂; a total number of the memory cells respectively corresponding to the test codes MSM3 and MSM4 may be changed by adjusting the applied transition read voltage V(i)₆; a total number of the memory cells respectively corresponding to the test codes MSU1 and MSU2 may be changed by adjusting the applied transition read voltage V(i)₁; a total number of the memory cells respectively corresponding to the test codes MSU3 and MSU4 may be changed by adjusting the applied transition read voltage V(i)₃; a total number of the memory cells respectively corresponding to the test codes MSUS and MSU6 may be changed by adjusting the applied transition read voltage V(i)₅; a total number of the memory cells respectively corresponding to the test codes MSU7 and MSUS may be changed by adjusting the applied transition read voltage V(i)₇.

By analogy, with reference to FIG. 8B, after the test code setting operation is executed for all the physical pages of the rewritable non-volatile memory module 220 in the second read voltage mode (2/3/2), as shown by an arrow A82, the test code management circuit 2151 can obtain and record: eight test codes MSL1, MSL2, MSL3, MSL4, MSLS, MSL6, MSL7 and MSL8 corresponding to the lower physical page (respectively having the bit value sets “111”, “011”, “001”, “000”, “010”, “110”, “100” and “101”), where the eight test codes MSL1, MSL2, MSL3, MSL4, MSLS, MSL6, MSL7 and MSL8 correspond to the transition read voltages V(i)₁ and V(i)₅ and the separate read voltages V(i)₂, V(i)₃, V(i)₄, V(i)₆ and V(i)₇; eight test codes MSM1, MSM2, MSM3, MSM4, MSMS, MSM6, MSM7 and MSM8 corresponding to the middle physical page (respectively having the bit value sets “111”, “011”, “001”, “000”, “010”, “110”, “100” and “101”), where the eight test codes MSM1, MSM2, MSM3, MSM4, MSMS, MSM6, MSM7 and MSM8 correspond to the transition read voltages V(i)₂, V(i)₄ and V(i)₆ and the separate read voltages V(i)₁, V(i)₃, V(i)₅ and V(i)₇; eight test codes MSU1, MSU2, MSU3, MSU4, MSUS, MSU6, MSU7 and MSU8 corresponding to the upper physical page (respectively having the bit value sets “111”, “011”, “001”, “000”, “010”, “110”, “100” and “101”), where the eight test codes MSU1, MSU2, MSU3, MSU4, MSUS, MSU6, MSU7 and MSU8 correspond to the transition read voltages V(i)₃ and V(i)₇ and the separate read voltages V(i)₁, V(i)₂, V(i)₄, V(i)₅ and V(i)₆.

It should be noted that, after fixing the applied separate read voltage of the corresponding physical page, a total number of the memory cells respectively corresponding to the test codes MSL1 and MSL2 may be changed by adjusting the applied transition read voltage V(i)₁; a total number of the memory cells respectively corresponding to the test codes MSLS and MSL6 may be changed by adjusting the applied transition read voltage V(i)₅; a total number of the memory cells respectively corresponding to the test codes MSM2 and MSM3 may be changed by adjusting the applied transition read voltage V(i)₂; a total number of the memory cells respectively corresponding to the test codes MSM4 and MSMS may be changed by adjusting the applied transition read voltage V(i)₄; a total number of the memory cells respectively corresponding to the test codes MSM6 and MSM7 may be changed by adjusting the applied transition read voltage V(i)₆; a total number of the memory cells respectively corresponding to the test codes MSU3 and MSU4 may be changed by adjusting the applied transition read voltage V(i)₃; a total number of the memory cells respectively corresponding to the test codes MSU7 and MSU 8 may be changed by adjusting the applied transition read voltage V(i)₇.

Returning to FIG. 3B, in step S40, the test code management circuit 2151 can determine whether the total number of the Q transition read voltages is greater than a preset threshold. Here, in response to determining that the total number of the Q transition read voltages is not greater than the predetermined threshold, step S35 is executed; in response to determining that the total number of the Q transition read voltages is greater than the predetermined threshold, step S41 is executed. The preset threshold is determined according to the read voltage mode of the rewritable non-volatile memory module 220. In this embodiment, for the rewritable non-volatile memory module 220 in the first read voltage mode (1/2/4), the preset threshold may be set to 3.

In step S41, the test code management circuit 215 directly sets a plurality of gray codes of the memory cells as a plurality of test codes corresponding to the target physical page to complete the test code setting operation corresponding to the target physical page.

For instance, it is assumed that the target physical page is the upper physical page, and the upper physical page corresponds to four transition read voltages. Since the total number of the transition read voltages corresponding to the upper physical page (i.e., Q) is greater than three, the test code management circuit 2151 directly uses the corresponding gray codes “111”, “110”, “100”, “101”, “001”, “000”, “010” and “011” as a plurality of test codes MSU1, MSU2, MSU3, MSU4, MSUS, MSU6, MSU7 and MSU8 corresponding to the upper physical page (as shown by FIG. 4).

Returning to FIG. 2A, in step S22, after the test codes corresponding to the target physical page are identified by the test code management circuit 2151 (e.g., by searching for the test codes recorded after the test code setting operation is completed), the test code management circuit 2151 identifies the Q transition read voltages corresponding to the P test codes in the preset read voltage set according to the preset read voltage set corresponding to the target word line.

Next, in step S23, the test code management circuit 2151 sets Q test read voltage sets respectively corresponding to the Q transition read voltages, wherein each of the Q test read voltage sets includes X test read voltages, and voltage values of the X test read voltages are set by a voltage value of the corresponding transition read voltage and a test voltage offset.

Next, in step S24, the read voltage management circuit unit 2151 uses the Q transition read voltages and the corresponding Q test read voltage sets to read the target word line to obtain Q test code count difference sets corresponding to the Q test read voltage sets.

Specifically, the step of “setting the Q test read voltage sets respectively corresponding to the Q transition read voltages (step S23)” may include steps (S23-1) to (S23-7): step (S23-1): for a first transition read voltage among the Q transition read voltages, identifying a first target test code corresponding to the first transition read voltage among the test codes; step (S23-2): generating a leftward adjusted transition read voltage and a rightward adjusted transition read voltage according to the first transition read voltage and the test voltage offset, wherein a voltage value of the leftward adjusted transition read voltage is a difference obtain by subtracting the test voltage offset from the voltage value of the first transition read voltage, wherein a voltage value of the rightward adjusted transition read voltage is a sum obtain by adding the test voltage offset to the voltage value of the first transition read voltage; step (S23-3): using the first transition read voltage to read the target word line to identify a total number of the memory cells with the storage states being the first target test code in the target word line as an original first target test code count; step (S23-4): using the leftward adjusted transition read voltage to read the target word line to identify the total number of the memory cells with the storage states being the first target test code in the target word line as a leftward adjusted first target test code count, and using an absolute difference obtained by subtracting the leftward adjusted first target test code count from the original first target test code count as a leftward adjusted first target test code count difference; step (S23-5): using the rightward adjusted transition read voltage to read the target word line to identify the total number of the memory cells with the storage states being the first target test code in the target word line as a rightward adjusted first target test code count, and using an absolute difference obtained by subtracting the rightward adjusted first target test code count from the original first target test code count as a rightward adjusted first target test code count difference; step (S23-6): in response to the leftward adjusted first target test code count difference being less than the rightward adjusted first target test code count difference, determining that the first transition read voltage needs a leftward adjustment, and respectively subtracting 1 to X times the test voltage offset from the voltage value of the first transition read voltage to generate the X test read voltages of a first test read voltage set corresponding to the first transition read voltage; and step (S23-7): in response to a rightward adjusted first target test code count difference being less than a leftward adjusted first target test code count difference, determining that the first transition read voltage needs a rightward adjustment, and respectively adding 1 to X times the test voltage offset to the voltage value of the first transition read voltage to generate the X test read voltages of the first test read voltage set corresponding to the first transition read voltage.

For instance, it is assumed that the target physical page is the lower physical page. The test code management circuit 2151 can identify the bit value sets of the two test codes MSL1 and MSL2 (P is equal to 2) as “1” and “0”, and the two test codes MSL1 and MSL2 correspond to one transition read voltage V(i)₄ (step S22).

In other words, the test code management circuit 2151 selects a fourth read voltage in the current read voltage set corresponding to the target word line and starts generating the corresponding test read voltage set. In this example, the read voltage set corresponding to the target word line is the preset read voltage set V(1). The test code management circuit 2151 can identify one transition read voltage V(1)₄ corresponding to the two test codes MSL1 and MSL2 corresponding to the lower physical page of the target word line in the preset read voltage set according to the preset read voltage set

V(1) corresponding to the target word line so the test code management circuit 2151 can then start executing step S23 to set the test read voltage set corresponding to the transition read voltage V(1)₄ (a.k.a. the first transition read voltage).

First of all, for the first transition read voltage V(1)₄, the test code management circuit 2151 identifies the first target test code corresponding to the first transition read voltage V(1)₄ in the test codes MSL1 and MSL2. In this embodiment, the first target test code may be one of the test codes MSL1 and MSL2 (the test code management circuit 2151 can select the test code at the left or the right from the paired two test codes corresponding to the first transition read voltage as the first target test code).

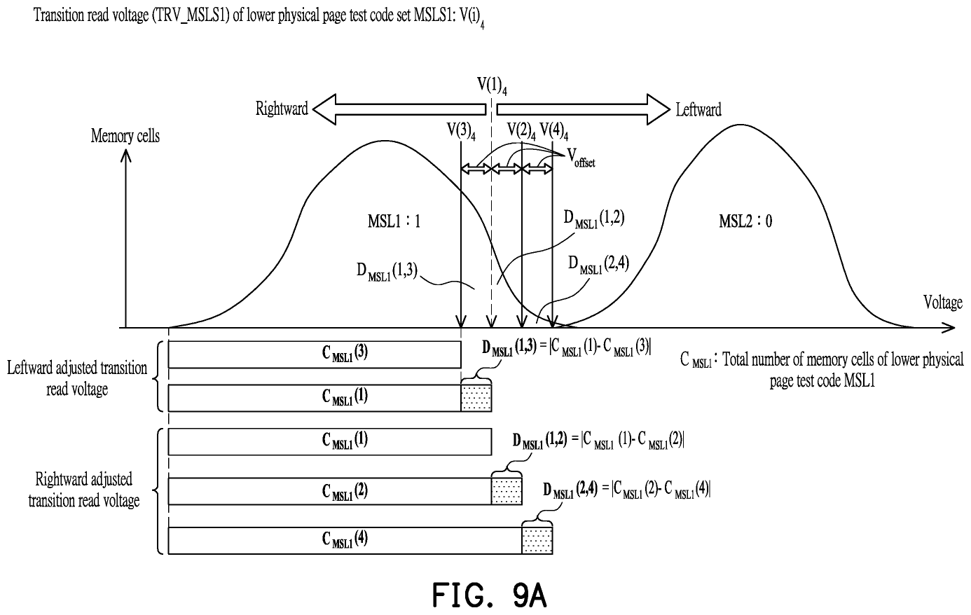

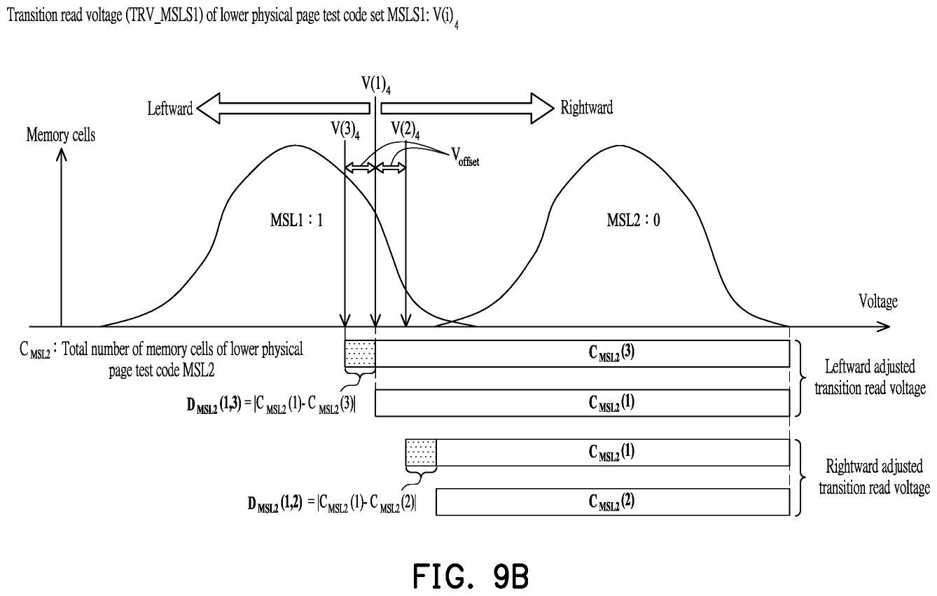

FIG. 9A is a schematic diagram illustrating a leftward adjusted transition read voltage and a rightward adjusted transition read voltage corresponding to a lower physical page according to an embodiment of the invention. With reference to FIG. 9A, in this embodiment, the test code management circuit 2151 selects the test code MSL1 as the first target test code corresponding to the first transition read voltage V(1)₄ (step S23-1). Here, it is assumed that threshold voltage distributions of the lower physical page of the memory cells of the target word line and a voltage value of the first transition read voltage V(1)₄ are as shown by FIG. 9A.

Next, with use of a test voltage offset V_{offset} to perform a rightward adjustment (to add the test voltage offset V_{offset}) or a leftward adjustment (to subtract the test voltage offset V_{offset}) on the first transition read voltage V(1)₄, the test code management circuit 2151 can generate a rightward adjusted transition read voltage V(2)₄ or a leftward adjusted transition read voltage V(3)₄ (step S23-2).

Next, the test code management circuit 2151 uses the first transition read voltage V(1)₄ to read the target word line to identify a total number of the memory cells with the storage states being the first target test code MSL1 (i.e., “1”) in the lower physical page of the target word line as an original first target test code count C_{MSL1}(1) (step S23-3). In addition, the test code management circuit 2151 uses the leftward adjusted transition read voltage V(3)₄ to read the target word line to identify a total number of the memory cells with the storage states being the first target test code MSL1 (i.e., “1”) in the target word line as a leftward adjusted first target test code count C_{MSL1}(3), and uses an absolute difference obtained by subtracting the leftward adjusted first target test code count C_{MSL1}(3) from the original first target test code count C_{MSL1}(1) as a leftward adjusted first target test code count difference D_{MSL1}(1,3) (step S23-4). Similarly, the test code management circuit 2151 uses the rightward adjusted transition read voltage V(2)₄ to read the target word line to identify the memory cells with the storage state being the first target test code MSL1 (i.e., “1”) in the target word line as a rightward adjusted first target test code count C_{MSL1}(2), and uses an absolute difference obtained by subtracting the rightward adjusted first target test code count C_{MSL1}(2) from the original first target test code count C_{MSL1}(1) as a rightward adjusted first target test code count difference D_{MSL1}(1,2) (step S23-5). It should be noted that, the order of step (S23-4) and step (S23-5) may be changed.

In addition, the invention does not limit the selected first target test code to be the left test code or the right test code among the two test codes, which may be decided by the manufacturers in advance.

FIG. 9B is a schematic diagram illustrating a leftward adjusted transition read voltage and a rightward adjusted transition read voltage corresponding to a lower physical page according to another embodiment of the invention. With reference to FIG. 9B, in this embodiment, the test code management circuit 2151 selects the test code MSL2 as the first target test code corresponding to the first transition read voltage V(1)₄ (step S23-1). In addition, as similar to the description for FIG. 9A, the test code management circuit 2151 can generate a rightward adjusted transition read voltage V(2)₄ and a leftward adjusted transition read voltage V(3)₄ (step S23-2). Next, the test code management circuit 2151 uses the first transition read voltage V(1)₄ to read the target word line to identify an original first target test code count C_{MSL2}(1)(step S23-3). In addition, the test code management circuit 2151 uses the leftward adjusted transition read voltage V(3)₄ to read the target word line to identify the leftward adjusted first target test code count C_{MSL2}(3) and obtains a leftward adjusted first target test code count difference D_{MSL2}(1,3) (step S23-4). Similarly, the test code management circuit 2151 uses the rightward adjusted transition read voltage V(2)₄ to read the target word line to identify a rightward adjusted first target test code count C_{MSL2}(2), and obtains a rightward adjusted first target test code count difference D_{MSL2}(1,2) (step S23-5).

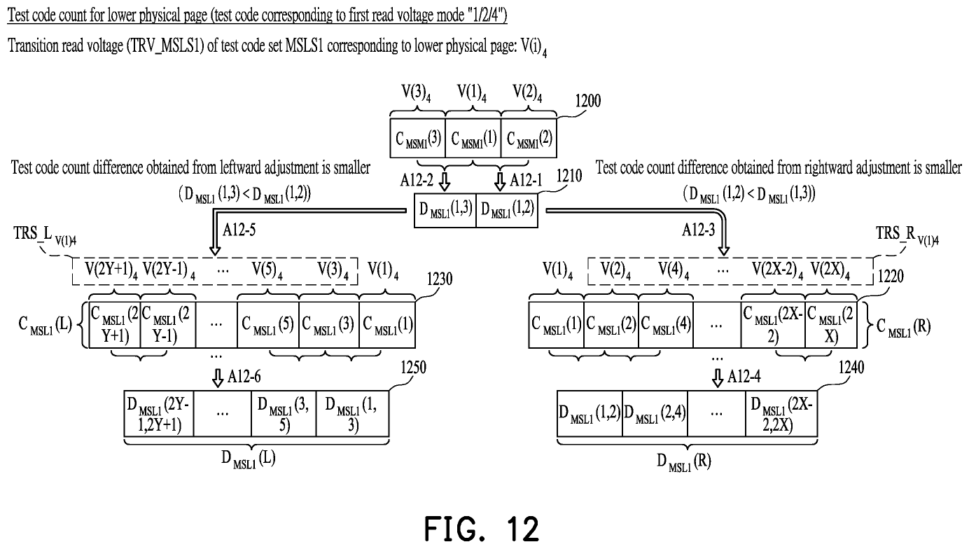

FIG. 12 is a schematic diagram for setting a test read voltage set corresponding to a transition read voltage of the lower physical page according to an embodiment of the invention. With reference to FIG. 12, in continuation with the example from FIG. 9A, it is assumed that the test code management circuit 2151 obtains the original first target test code count _{MSL1}(1), the leftward adjusted first target test code count C_{MSL1}(3) and the rightward adjusted first target test code count C_{MSL1}(2) through the first transition read voltage V(1)₄ (e.g., as shown by a table 1200). Next, as shown by arrows 12-1 and 12-2, the test code management circuit 2151 uses the original first target test code count C_{MSL1}(1), the leftward adjusted first target test code count C_{MSL1}(3) and the rightward adjusted first target test code count C_{MSL1}(2) to calculate the leftward adjusted first target test code count difference D_{MSL1}(1,3) and the rightward adjusted first target test code count difference D_{MSL1}(1,2).

Next, the test code management circuit 2151 can first compare sizes of the leftward adjusted first target test code count difference D_{MSL1}(1,3) and the rightward adjusted first target test code count difference D_{MSL1}(1,2), so as to determine whether the leftward or rightward adjustment is needed for generating the test read voltage set based on the first transition read voltage V(1)₄.

Specifically, referring to FIG. 9A first, in the example of FIG. 9A, in view of the threshold voltage distributions corresponding to the test codes MSL1 and MSL2, a size of a first area of the threshold voltage distribution included between the first transition read voltage V(1)₄ and the rightward adjusted transition read voltage V(2)₄ corresponds to the rightward adjusted first target test code count difference D_{MSL1}(1,2), a size of a second area of the threshold voltage distribution included between the first transition read voltage V(1)₄ and the leftward adjusted transition read voltage V(3)₄ corresponds to the leftward adjusted first target test code count difference D_{MSL1}(1,3), and the first area is smaller than the second area. In other words, in this example, the rightward adjusted first target test code count difference D_{MSL1}(1,2) is less than the leftward adjusted first target test code count difference D_{MSL1}(1,3). In addition, after the rightward adjustment is performed on the first transition read voltage V(1)₄, the rightward adjusted transition read voltage V(2)₄ underwent the adjustment is closer to an intersection between the threshold voltage distributions of the test codes MSL1 and MSL2.

Accordingly, in response to the rightward adjusted first target test code count difference D_{MSL1}(1,2) being less than the leftward adjusted target test code count difference D_{MSL1}(1,3), the test code management circuit 2151 determines that the first transition read voltage V(1)₄ needs the rightward adjustment (to be closer to the intersection between the threshold voltage distributions of the test codes MSL1 and MSL2). Next, referring to FIG. 12, as shown by an arrow A12-3, in response to the rightward adjusted first target test code count difference D_{MSL1}(1,2) being less than the leftward adjusted first target test code count difference D_{MSL1}(1,3), the test code management circuit 2151 respectively adds 1 to X times the test voltage offset to the voltage value of the first transition read voltage to generate X test read voltages V(2)₄, V(4)₄ to V(2X−2)₄ and V(2X)₄ of a first test read voltage set TRS_R_{V(1)4} corresponding to the first transition read voltage (step S23-6). For example, the test read voltage V(4)₄ is a sum obtained by adding 2*V_{offset} to the first transition read voltage V(1)₄.

Relatively, as shown by an arrow A12-5, in an embodiment, in response to the leftward adjusted target test code count difference D_{MSL1}(1,3) being less than the rightward adjusted target test code count difference D_{MSL1}(1,2), the test code management circuit 2151 determines that the first transition read voltage V(1)₄ needs the leftward adjustment, and can then respectively subtract 1 to Y times the test voltage offset from the voltage value of the first transition read voltage to generate Y test read voltages V(3)₄, V(5)₄ to V(2Y−1)₄ and V(2Y+1)₄ of a first test read voltage set TRS_L_{V(1)4} corresponding to the first transition read voltage (step S23-7). Said Y may be equal to X, and X and Y are positive integers. For example, the test read voltage V(5)₄ is a difference obtained by subtracting 2*V_{offset} from the first transition read voltage V(1)₄.

In other words, in this embodiment, the test code management circuit 2151 determines whether the first transition read voltage needs the leftward adjustment or the rightward adjustment by comparing the sizes of the leftward adjusted first target test code count difference D_{MSL1}(1,3) and the rightward adjusted first target test code count difference D_{MSL1}(1,2), and then generates the corresponding test read voltage set according to the determined adjustment direction. In this way, the suitable test read voltage group (for closing to the intersection of the threshold voltage distributions) can be generated more efficiently. It should be noted that, values of the X and Y are not particularly limited in the invention.

More specifically, in this embodiment, a determination result from determining whether the test codes corresponding to the target physical page corresponds to the separate read voltage can affect the test code management circuit 2151 in determining whether to use the separate read voltage to read the target word line to obtain the test code count difference.

FIG. 2B is a flowchart illustrating step S24 of FIG. 2A according to an embodiment of the invention. Referring to FIG. 2B, step S24 includes steps S241 to S244. In step S241, the test code management circuit 2151 determines whether the P test codes correspond to one or more separate read voltages (e.g., R separate read voltages, R is an integer). Here, in response to determining that the P test codes do not correspond to one or more separate read voltages (the P test codes do not correspond to any separate read voltage), step S242 is executed; in response to determining that the P test codes do correspond to one or more separate read voltages, step S243 is executed.

In step S242, the read voltage management circuit unit 2151 uses the Q transition read voltages and the corresponding Q test read voltage sets to read the target word line to obtain Q test code count difference sets corresponding to the Q test read voltage sets.

For instance, referring to FIG. 9A first, in this example, after setting the Q transition read voltage sets corresponding to the Q transition read voltages, the test code management circuit 2151 determines that the test codes MSL1 and MSL2 do not correspond to any separate read voltage (step S241→No). Then, the read voltage management circuit unit 2151 uses the Q transition read voltages and the corresponding Q test read voltage sets to read the target word line to obtain Q test code count difference sets corresponding to the Q test read voltage sets (step S242).

More specifically, the step of “using the Q transition read voltages and the corresponding Q test read voltage sets to read the target word line to obtain Q test code count difference sets corresponding to the Q test read voltage sets” includes steps (S242-1) to (S242-4): (S242-1): for the first transition read voltage among the Q transition read voltages, identifying the first target test code corresponding to the first transition read voltage among the test codes and the first test read voltage set corresponding to the first transition read voltage among the Q test read voltage sets; (S242-2): using the first transition read voltage to read the target word line to identify the total number of the memory cells with the storage states being the first target test code in the target word line as the original first target test code count; (S242-3): respectively using X first test read voltages of the first test read voltage set to read the target word line to obtain X first target test code counts, wherein a jth first target test code count among the X first target test code counts is a total number of the memory cells being the first target test code identified by using a jth first test read voltage among the X first test read voltages to read the target word line; and (S242-4): calculating X first test code count differences for forming a first test code count difference set corresponding to the first test read voltage set among the Q test code count difference sets according to the original first target test code count and the X first target test code counts.

Referring to FIG. 9A and FIG. 12 together, in this example, it is assumed that X is set to 2, that is, the test read voltage set TRS_RV(1)₄ corresponding to the first transition read voltage V(1) includes the transition read voltage V(2)₄ and the transition read voltage V(4)₄.

For the first transition read voltage V(1)₄, the test code management circuits 2151 identifies the first target test code MSL1 corresponding to the first transition read voltage V(1)₄ among the test codes MSL1 and MSL2 and the first test read voltage set TRS_R_{V(1)4} corresponding to the first transition read voltage V(1)₄ (S242-1).

Next, the test code management circuit 2151 uses the first transition read voltage V(1)₄ to read the target word line to identify a total number of the memory cells with the storage states being the first target test code MSL1 in the target word line as the original first target test code count C_{MSL1}(1) (step S242-2).

Next, the test code management circuit 2151 respectively uses two first test voltages V(2)₄ and V(4)₄ of the first test read voltage set TRS_R_{V(1)4} in sequence to read the target word line, so as to obtain two first target test code counts C_{MSL1}(2) and C_{MSL1}(4) (S242-3).

Next, according to the original first target test code count C_{MSL1}(1) and the two first target test code counts C_{MSL1}(2) and C_{MSL1}(4), the test code management circuit 2151 calculates two first test code count differences D_{MSL1}(1,2) and D_{MSL1}(2,4), so as to form a first test code count difference set D_{MSL1}(R) corresponding to the first test read voltage set TRS_R_{V(1)4} (S242-4).

In other words, after setting the test read voltage set TRS_R_{V(1)4} corresponding to the transition read voltage V(1)₄ (through the rightward adjustment), the test code management circuit 2151 uses the transition read voltage V(1)₄ and all the test read voltages in the test read voltage set TRS_R_{V(1)4} in sequence to read the target word line, so as to obtain a corresponding test code count set C_{MSL1}(R), as shown by a table 1220. Next, as shown by an arrow A12-4, according to the test code count set C_{MSL1}(R), the test code management circuit 2151 calculates the first test code count difference set D_{MSL1}(R) corresponding to the first test read voltage set TRS_R_{V(1)4}, as shown by a table 1240. Conversely, after setting the test read voltage set TRS_L_{V(1)4} corresponding to the transition read voltage V(1)₄ (through the leftward adjustment), the test code management circuit 2151 uses the transition read voltage V(1)₄ and all the test read voltages in the test read voltage set TRS_L_{V(1)4} to read the target word line, so as to obtain a corresponding test code count set C_{MSL1}(L), as shown by a table 1230. Next, as shown by an arrow Al2-6, according to the test code count set C_{MSL1}(L), the test code management circuit 2151 calculates a first test code count difference set D_{MSL1}(L) corresponding to the first test read voltage set TRS_L_{V(1)4}, as shown by a table 1250.

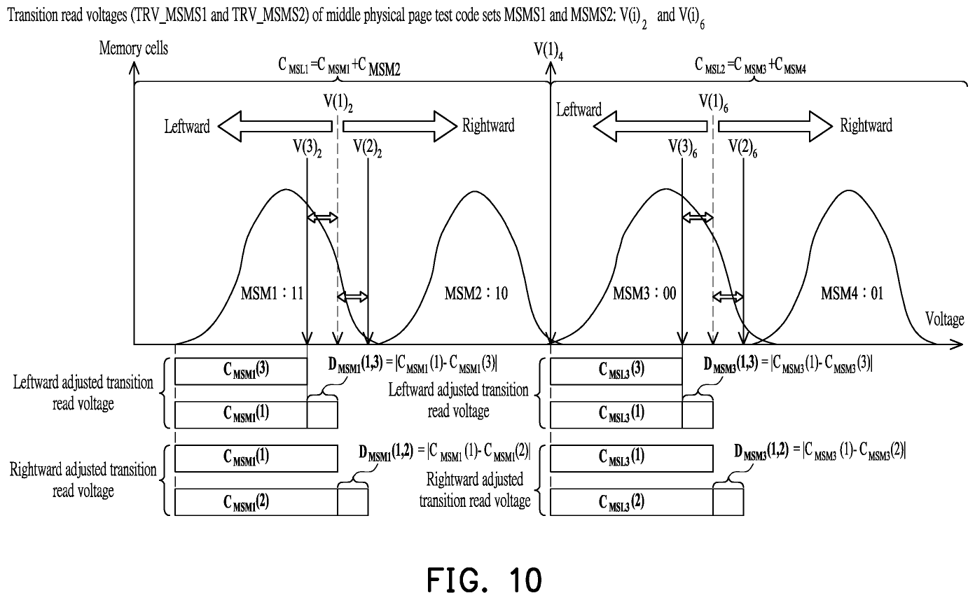

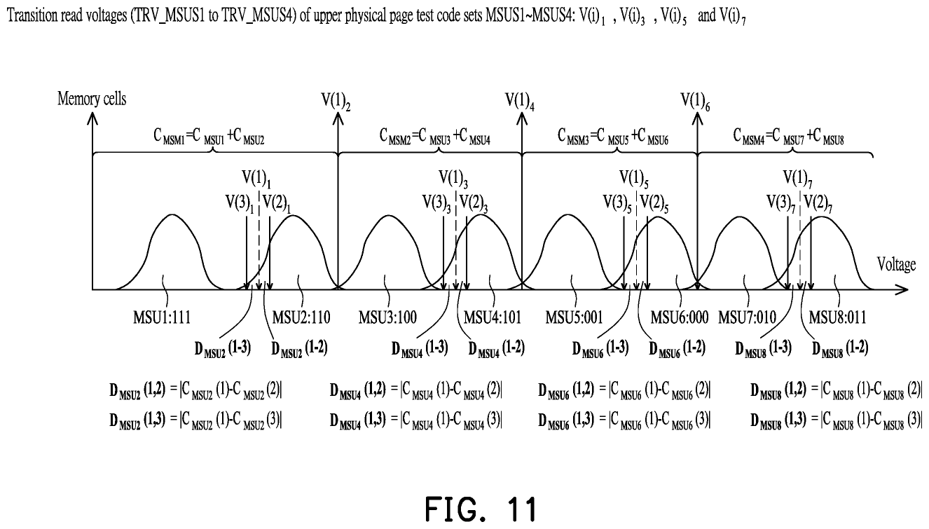

Returning to FIG. 2B, in step S243, the test code management circuit 2151 identifies voltage values of the R separate read voltages according to the preset read voltage set corresponding to the target word line. Specifically, in this embodiment, if the target physical page is the middle physical page or the upper physical page, the test codes of the middle physical page or the upper physical page will correspond to one or three separate read voltages. R is used to represent a total number of the separate read voltages corresponding to the test codes of the target physical page, and R may be zero or a positive integer. The leftward adjusted transition read voltage and the rightward adjusted transition read voltage corresponding to the middle and upper physical pages are introduced below with reference to FIGS. 10 and 11.

FIG. 10 is a schematic diagram illustrating a leftward adjusted transition read voltage and a rightward adjusted transition read voltage corresponding to a middle physical page according to an embodiment of the invention. For instance, referring to FIG. 10, in this example, the target physical page is the middle physical page, and the test code management circuit 2151 identifies test codes MSM1 to MSM4 corresponding to the middle physical page, transition read voltages V(i)₂ and V(i)₆ corresponding to the test codes MSM1 to MSM4, and a separate read voltage V(i)₄ corresponding to the test codes MSM1 to MSM4 (step S243). In this embodiment, for a transition read voltage V(1)₂, the test code management circuit 2151 selects the test code MSM1 as a target test code corresponding to the transition read voltage V(1)₂ (step S23-1). The test code management circuit 2151 can generate a rightward adjusted transition read voltage V(2)₂ and a leftward adjusted transition read voltage V(3)₂ (step S23-2). Next, the test code management circuit 2151 uses the transition read voltage V(1)₂ to read the target word line to identify an original first target test code count C_{MSM1}(1) (step S23-3). In addition, the test code management circuit 2151 uses the leftward adjusted transition read voltage V(3)₂ to read the target word line to identify a leftward adjusted first target test code count C_{MSM1}(3), and obtains a leftward adjusted first target test code count difference D_{MSM1}(1,3) (step S23-4). Similarly, the test code management circuit 2151 uses the rightward adjusted transition read voltage V(2)₂ to read the target word line to identify the rightward adjusted first target test code count C_{MSM2}(2), and obtains the rightward adjusted first target test code count difference D_{MSM2}(1,2) (step S23-5).

Similarly, at the same time, for the transition read voltage V(1)₆, the test code management circuit 2151 selects the test code MSM3 as a target test code corresponding to the transition read voltage V(1)₆ (step S23-1). The test code management circuit 2151 can generate a rightward adjusted transition read voltage V(2)₆ and a leftward adjusted transition read voltage V(3)₆ (step S23-2). Next, the test code management circuit 2151 uses the transition read voltage V(1)₆ to read the target word line to identify an original first target test code count C_{MSM3}(1) (step S23-3). In addition, the test code management circuit 2151 uses the leftward adjusted transition read voltage V(3)₆ to read the target word line to identify the leftward adjusted first target test code count C_{MSM3}(3) and obtains the leftward adjusted first target test code count difference D_{MSM3}(1,3) (step S23-4). Similarly, the test code management circuit 2151 uses the rightward adjusted transition read voltage V(2)₆ to read the target word line to identify the rightward adjusted first target test code count C_{MSM3}(2), and obtains the rightward adjusted first target test code count difference D_{MSM3}(1,2) (step S23-5).

It is worth noting that, in this example, a sum of a total number of the memory cells corresponding to the test code MSM1 (i.e., the test code count C_{MSM1}) and a total number of the memory cells corresponding to the test code MSM2 (i.e., the test code count C_{MSM2}) is equal to a total number of the memory cells corresponding to the test code MSL1 (i.e., the test code count C_{MSL1}). Therefore, the applied separate read voltage V(1)₄ needs to be fixed (not adjusted). Only by doing so, the test code count C_{MSL1} and the test code count C_{MSL2} can be fixed so the test read voltage (i.e., V(2)₂) adjusted from the transition read voltage V(1)₂ and the test read voltage (e.g., V(2)₆) adjusted from the transition read voltage V(1)₆ may be applied to the target word line together without causing mutual interference on the obtained target test code counts C_{MSM1} and C_{MSM3} (or the target test code counts C_{MSM2} and C_{MSM4}).

FIG. 11 is a schematic diagram illustrating a leftward adjusted transition read voltage and a rightward adjusted transition read voltage corresponding to an upper physical page according to an embodiment of the invention. For instance, referring to FIG. 11, in this example, the target physical page is the upper physical page, and the test code management circuit 2151 identifies test codes MSU1 to MSU8 corresponding to the upper physical page, transition read voltages V(1)₁, V(1)₃, V(1)₅ and V(1)₇ corresponding to the test codes MSU1 to MSU8, and separate read voltages V(1)₂, V(1)₄ and V(1)₆ corresponding to the test codes MSU1 to MSU8. As similar to the process in FIG. 10, by selecting the corresponding target test codes MSU2, MSU4, MSU6 and MSU8, a rightward adjusted transition read voltage V(2)₁ and a leftward adjusted transition read voltage V(3)₁ may be generated in correspondence to the transition read voltage V(1)₁; a rightward adjusted transition read voltage V(2)₃ and a leftward adjusted transition read voltage V(3)₃ may be generated in correspondence to the transition read voltage V(1)₃; a rightward adjusted transition read voltage V(2)₅ and a leftward adjusted transition read voltage V(3)₅ may be generated in correspondence to the transition read voltage V(1)₅; a rightward adjusted transition read voltage V(2)₇ and a leftward adjusted transition read voltage V(3)₇ may be generated in correspondence to the transition read voltage V(1)₇. Next, the test code management circuit 2151 can correspondingly apply the transition read voltages V(1)₁, V(1)₃, V(1)₅ and V(1)₇, the rightward adjusted transition read voltages V(2)₁, V(2)₃, V(2)₅ and V(2)₇, and the leftward adjusted transition read voltages V(3)₁, V(3)₃, V(3)₅ and V(3)₇ to read the target word line, so as to obtain corresponding test code count differences D_{MSU2}(1,2), D_{MSU4}(1,2), D_{MSU6}(1,2), D_{MSU8}(1,2), D_{MSU2}(1,3), D_{MSU4}(1,3), D_{MSU6}(1,3) and D_{MSU8}(1,3).

It is worth noting that, in this example, based on the same reason why the separate read voltage needs to be fixed, the test code management circuit 2151 fixes the separate read voltages V(1)₂, V(1)₄ and V(1)₆. In this way, the test code count C_{MSM1}, the test code count C_{MSM2}, the test code count C_{MSM3} and the test code count C_{MSM4} may be fixed so the test read voltage (e.g., V(2)₁) adjusted from the transition read voltage V(1)₁, the test read voltage (e.g., V(2)₃) adjusted from the transition read voltage V(1)₃, the test read voltage (e.g., V(2)₅) adjusted from the transition read voltage V(1)₅, the test read voltage (e.g., V(2)₇) adjusted from the transition read voltage V(1)₇ may be applied to the target word line together without causing mutual interference to the obtained target test code counts C_{MSU2}, C_{MSU4}, C_{MSU6} and C_{MSU8} (or the target test code counts C_{MSU1}, C_{MSU3}, C_{MSU5} and C_{MSU7}).

Returning to FIG. 2B, in step S244, the read voltage management circuit unit 2151 uses the R separate read voltages, the Q transition read voltages and the corresponding Q test read voltage sets to read the target word line to obtain Q test code count difference sets corresponding to the Q test read voltage sets. As similar to step S242, in step S244, before the Q transition read voltages and the corresponding Q test read voltage sets are used to read the target word line, the R separate read voltages are used first to read the target word line in order to fix the corresponding test code count (as shown in FIG. 11, according to an arrangement order of the physical pages, the separate read voltages V(1)₄, V(1)₂ and V(1)₆ are used first to fix values of the test code count C_{MSM1}, the test code count C_{MSM2}, the test code count C_{MSM3} and the test code count C_{MSM4}), so that the subsequent four transition read voltages and the corresponding four test read voltages may be applied to the target word line at the same time without causing mutual interference on the obtained target test code counts C_{MSU2}, C_{MSU4}, C_{MSU6} and C_{MSU8} (or the target test code counts C_{MSU1}, C_{MSU3}, C_{MSU5} and C_{MSU7}). It should be noted that the above concept can also be considered as using the transition read voltages of the physical pages other than the target physical page as the separate read voltages, which may be used as boundaries of the test code sets of the target physical page. When the boundaries are fixed (not adjusted), no matter how the transition read voltages in the test code sets are adjusted, the test code counts in the other test code sets will not be influenced.

It is worth noting that, the operation of “applying the adjusted transition read voltages corresponding to the target physical page at the same time” can reduce a read count for obtaining the test code counts while improving the efficiency for obtaining the corresponding test code counts. For example, the test code management circuit 2151 can apply four transition read voltages V(1)₁, V(1)₃, V(1)₅ and V(1)₇ at the same time to perform one reading, so as to obtain the corresponding original target test code counts C_{MSU2}, C_{MSU4}, C_{MSU6} and C_{MSU8}. Similarly, if the four transition read voltages V(1)₁, V(1)₃, V(1)₅ and V(1)₇ cannot be applied at the same time, the test code management circuit 2151 needs to apply the transition read voltages V(1)₁, V(1)₃, V(1)₅ and V(1)₇(i.e., four readings) in sequence before the original target test code counts C_{MSU2}, C_{MSU4}, C_{MSU6} and C_{MSU8} can be obtained.

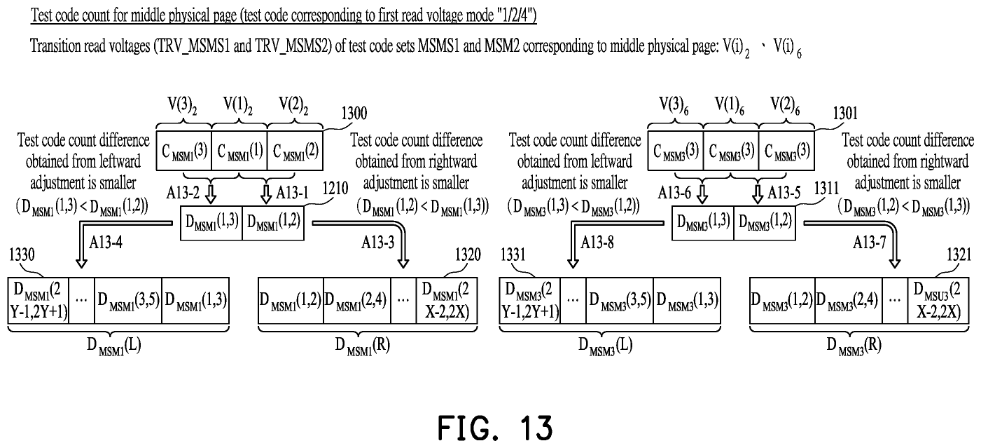

FIG. 13 is a schematic diagram for setting a plurality of test read voltage sets corresponding to a plurality of transition read voltages of the middle physical page according to an embodiment of the invention. For instance, referring to the FIG. 10 and FIG. 13 together, it is assumed that the target physical page is the middle physical page, and the middle physical page corresponds to the transition read voltages V(1)₂ and V(1)₆. For the transition read voltage V(1)₂ and the target test code MSM1, as shown by a table 1300, the test code management circuit 2151 can apply the read voltages V(1)₂, V(2)₂ and V(3)₂ to obtain corresponding target test code counts C_{MSM1}(1), C_{MSM1}(2) and C_{MSM1}(3). Next, as shown by arrows A13-1 and A13-2, the corresponding target test code count differences D_{MSM1}(1,2) and D_{MSM1}(1,3) may be obtained (as shown by a table 1310). Next, in response to the target test code count difference D_{MSM1}(1,2) being smaller, the test code management circuit 2151 generates the rightward adjusted test read voltage set according to the transition read voltage V(1)₂, and applies the generated test read voltage set to the target word line (as shown by an arrow A13-3), so as to obtain a corresponding test code count difference set D_{MSM1}(R), as shown by a table 1320; in response to the target test code count difference D_{MSM1}(1,3) being smaller, the test code management circuit 2151 generates the leftward adjusted test read voltage set according to the transition read voltage V(1)₂, and applies the generated test read voltage set to the target word line (as shown by an arrow A13-4), so as to obtain a corresponding test code count difference set D_{MSM1}(L), as shown by a table 1330.

Meanwhile, for the transition read voltage V(1)₆ and the target test code MSM3, as shown by a table 1301, the test code management circuit 2151 can apply the read voltages V(1)₆, V(2)₆ and V(3)₆ to obtain corresponding target test code counts C_{MSM3}(1), C_{MSM3}(2) and C_{MSM3}(3). Next, as shown by arrows A13-5 and A13-6, corresponding target test code count differences D_{MSM3}(1,2) and D_{MSM3}(1,3) may be obtained (as shown by a table 1311). Next, in response to the target test code count difference D_{MSM3}(1,2) being smaller, the test code management circuit 2151 generates the rightward adjusted test read voltage set according to the transition read voltage V(1)₆, and applies the generated test read voltage set to the target word line (as shown by an arrow A13-7), so as to obtain a corresponding test code count difference set D_{MSM3}(R), as shown by a table 1321; in response to the target test code count difference D_{MSM3}(1,3) being smaller, the test code management circuit 2151 generates the leftward adjusted test read voltage set according to the transition read voltage V(1)₆, and applies the generated test read voltage set to the target word line (as shown by an arrow A13-8), so as to obtain a corresponding test code count difference set D_{MSM3}(L), as shown by a table 1331.

It is worth noting that, in the example of FIG. 13, the adjustment directions of the transition read voltage V(1)₂ and the transition read voltage V(1)₆ may be different.

For example, it is assumed that the test code count difference obtained from the rightward adjusted transition read voltage V(1)₂ is smaller (D_{MSM1}(1,2)<D_{MSM1}(1,3)) and the test code count difference obtained from the leftward adjusted transition read voltage V(1)₆ is smaller (D_{MSM3}(1,3)<D_{MSM3}(1,2)). In this case, the rightward adjusted test read voltage set is generated according to the transition read voltage V(1)₂, and leftward adjusted test read voltage set is generated according to the transition read voltage V(1)₆. That is to say, the technical solution provided by the invention is able to generate the corresponding test read voltage sets from the different transition read voltages using the different adjustment directions. The difference between the invention and the conventional approaches is that: in the conventional approaches, for the transition read voltage on the same physical page, the same adjustment direction is used to generate the corresponding test read voltage sets without considering the suitable adjustment direction for each of the transition read voltages; however, the invention is able to further adjust the transition read voltages with the suitable adjustment direction to generate the corresponding test read voltage sets to thereby obtain better read voltage.

On the other hand, in an embodiment, it is assumed that the test code count difference obtained from the rightward adjusted transition read voltage V(1)₂ is smaller (D_{MSM1}(1,2)<D_{MSM1}(1,3)). In addition to the fact that the test code management circuit 2151 can generate the rightward adjusted test read voltage set, the test code management circuit 2151 is also able to further compare a size of the test code count difference D_{MSM1}(1,2) with a standard difference and adjust a size of the test voltage offset V_{offset} used by the test read voltage set, so as to speed up the convergence. For example, if the size of the test code count difference D_{MSM1}(1,2) is 1.5 times the standard difference, the test code management circuit 2151 can use 1.5 times the test voltage offset V_{offset} to generate the test read voltage set.

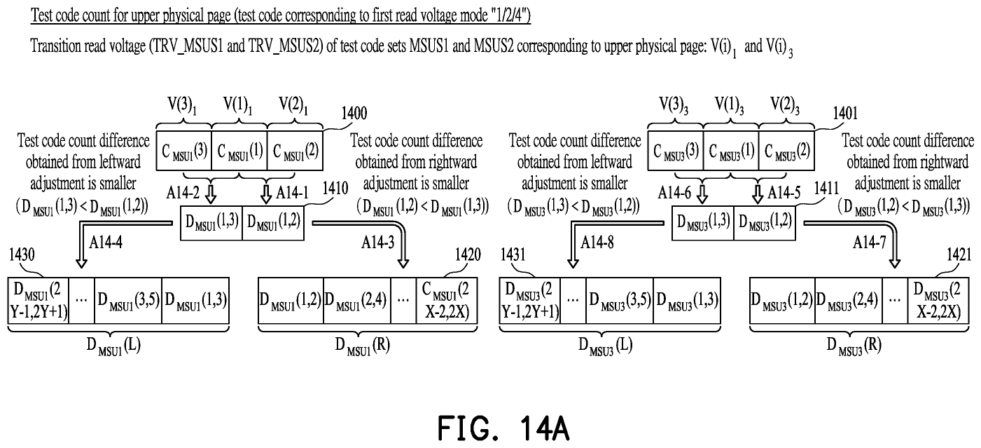

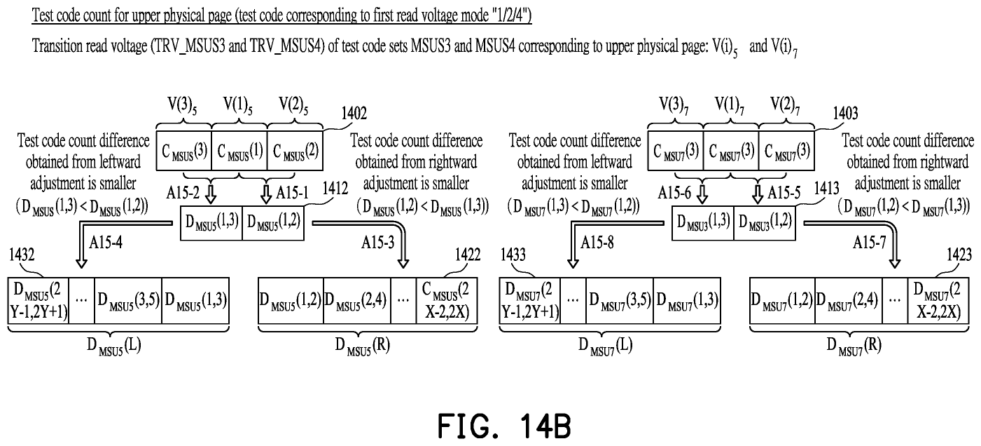

FIGS. 14A and 14B are schematic diagrams for setting a plurality of test read voltage sets corresponding to a plurality of transition read voltages of the upper physical page according to an embodiment of the invention. For instance, it is assumed that the target physical page is the upper physical page, and the upper physical page corresponds to the transition read voltages V(1)₁, V(1)₃, V(1)₅ and V(1)₇. With reference to FIG. 14A, for the transition read voltage V(1)₁ and the target test code MSU1, as shown by a table 1400, the test code management circuit 2151 can apply the read voltages V(1)₁, V(2)₁ and V(3)₁ to obtain corresponding target test code counts C_{MSU1}(1), C_{MSU1}(2) and C_{MSU1}(3). Next, as shown by arrows A14-1 and A14-2, the corresponding target test code count differences D_{MSU1}(1,2) and D_{MSU1}(1,3) may be obtained (as shown by a table 1410). Next, in response to the target test code count difference D_{MSU1}(1,2) being smaller, the test code management circuit 2151 generates the rightward adjusted test read voltage set according to the transition read voltage V(1)₁, and applies the generated test read voltage set to the target word line (as shown by an arrow A14-3), so as to obtain a corresponding test code count difference set D_{MSU1}(R), as shown by a table 1420; in response to the target test code count difference D_{MSU1}(1,3) being smaller, the test code management circuit 2151 generates the leftward adjusted test read voltage set according to the transition read voltage V(1)₁, and applies the generated test read voltage set to the target word line (as shown by an arrow A14-4), so as to obtain a corresponding test code count difference set D_{MSU1}(L), as shown by a table 1430.

Meanwhile, for the transition read voltage V(1)₃ and the target test code MSU3, as shown by a table 1401, the test code management circuit 2151 can apply the read voltages V(1)₃, V(2)₃ and V(3)₃ to obtain corresponding target test code counts C_{MSU3}(1), C_{MSU3}(2) and C_{MSU 3}(3). Next, as shown by arrows A14-5 and A14-6, the corresponding target test code count differences D_{MSU3}(1,2) and D_{MSU3}(1,3) may be obtained (as shown by a table 1411). Next, in response to the target test code count difference D_{MSU3}(1,2) being smaller, the test code management circuit 2151 generates the rightward adjusted test read voltage set according to the transition read voltage V(1)₃, and applies the generated test read voltage set to the target word line (as shown by an arrow A14-7), so as to obtain a corresponding test code count difference set D_{MSU3}(R), as shown by a table 1421; in response to the target test code count difference D_{MSU3}(1,3) being smaller, the test code management circuit 2151 generates the leftward adjusted test read voltage set according to the transition read voltage V(1)₃, and applies the generated test read voltage set to the target word line (as shown by an arrow A14-8), so as to obtain a corresponding test code count difference set D_{MSU3}(L), as shown by a table 1431.

Meanwhile, with reference to FIG. 14B, for the transition read voltage V(1)₅ and the target test code MSUS, as shown by a table 1402, the test code management circuit 2151 can apply the read voltages V(1)₅, V(2)₅ and V(3)₅ to obtain corresponding target test code counts C_{MSU5}(1), C_{MSU5}(2) and C_{MSU5}(3). Next, as shown by arrows A15-1 and A15-2, the corresponding target test code count differences D_{MSU5}(1,2) and D_{MSU5}(1,3) may be obtained (as shown by a table 1412). Next, in response to the target test code count difference D_{MSU5}(1,2) being smaller, the test code management circuit 2151 generates the rightward adjusted test read voltage set according to the transition read voltage V(1)₅, and applies the generated test read voltage set to the target word line (as shown by an arrow A15-3), so as to obtain a corresponding test code count difference set D_{MSU5}(R), as shown by a table 1422; in response to the target test code count difference D_{MSU5}(1,3) being smaller, the test code management circuit 2151 generates the leftward adjusted test read voltage set according to the transition read voltage V(1)₅, and applies the generated test read voltage set to the target word line (as shown by an arrow A15-4), so as to obtain a corresponding test code count difference set D_{MSU5}(L), as shown by a table 1432.

Meanwhile, for the transition read voltage V(1)₇ and the target test code MSU7, as shown by a table 1403, the test code management circuit 2151 can apply the read voltages V(1)₇, V(2)₇ and V(3)₇ to obtain corresponding target test code counts C_{MSU7}(1), C_{MSU7}(2) and C_{MSU7}(3). Next, as shown by arrows A15-5 and A15-6, the corresponding target test code count differences D_{MSU7}(1,2) and D_{MSU7}(1,3) may be obtained (as shown by a table 1413). Next, in response to the target test code count difference D_{MSU7}(1,2) being smaller, the test code management circuit 2151 generates the rightward adjusted test read voltage set according to the transition read voltage V(1)₇, and applies the generated test read voltage set to the target word line (as shown by an arrow A15-7), so as to obtain a corresponding test code count difference set D_{MSU7}(R), as shown by a table 1423; in response to the target test code count difference D_{MSU7}(1,3) being smaller, the test code management circuit 2151 generates the leftward adjusted test read voltage set according to the transition read voltage V(1)₇, and applies the generated test read voltage set to the target word line (as shown by an arrow A15-8), so as to obtain a corresponding test code count difference set D_{MSU7}(L), as shown by a table 1433.

Returning to FIG. 2A, after obtaining the corresponding Q test code count difference sets, in step S25, the read voltage optimization circuit 2152 obtains an optimized read voltage set corresponding to the target physical page according to the Q test code count difference sets, thereby completing the read voltage optimization operation corresponding to the target physical page. Specifically, step S25 includes: identifying a target test read voltage from the X test read voltages of each of the Q test read voltage sets to obtain Q target test read voltages corresponding to the Q test read voltage sets, and replacing the Q transition read voltages in the preset read voltage set by the Q target test read voltages to change the preset read voltage set to the optimized read voltage set.

More specifically, in the operation of “identifying a target test read voltage from the X test read voltages of each of the Q test read voltage sets to obtain Q target test read voltages corresponding to the Q test read voltage sets”, for the first test code count difference set corresponding to the first test read voltage set among the Q test code count difference sets and the first test read voltage set in the corresponding Q test read voltage sets, the read voltage optimization circuit 2152 identifies a smallest one among the X first test code count differences as a target first test code count difference according to sizes of the X first test code count differences of the first test code count difference set. Next, the read voltage optimization circuit 2152 selects one of two first target test code counts corresponding to the target first test code count difference, and identifies a target first test read voltage corresponding to the selected first target test code count from the X first test read voltages of the first test read voltage set. The target first test read voltage may be regarded as the optimized read voltage corresponding to the transition read voltage of the target physical page.

For instance, referring to FIG. 9A, in this example, it is assumed that the obtained test code count difference set includes two test code count differences D_{MSL1}(1,2) and D_{MSL1}(2,4) (X=2). Then, the read voltage optimization circuit 2152 compares sizes of the test code count differences D_{MSL1}(1,2) and D_{MSL1}(2,4). In this example, the test code count difference D_{MSL1}(2,4) is less than the test code count difference D_{MSL1}(1,2). That is to say, the test code management circuit 2151 identifies that the test code count difference D_{MSL1}(2,4) is the smallest one among the two test code count differences D_{MSL1}(1,2) and D_{MSL1}(2,4), and sets the test code count difference D_{MSL1}(2,4) as the target first test code count difference of the first test read voltage set corresponding to the first transition read voltage. Since the target test code count difference D_{MSL1}(2,4) is obtained by calculation with the first target test code count difference C_{MSL1}(2) and the first target test code count difference C_{MSL1}(4), the read voltage optimization circuit 2152 identifies that the target first test code count difference D_{MSL1}(2,4) corresponds to the first target test code count difference C_{MSL1}(2) and the first target test code count difference C_{MSL1}(4), identifies that the first target test code count difference C_{MSL1}(2) corresponds to the first target read voltage V(2)₄ of the two first target read voltages V(2)₄ and V(4)₄ in the first read voltage set, and identifies that the first target test code count difference C_{MSL1}(4) corresponds to the first target read voltage V(4)₄ of the first target read voltages V(2)₄ and V(4)₄ in the first read voltage set. Next, the read voltage optimization circuit 2152 can select one of the first target test code count C_{MSL1}(2) and the first target test code count C_{MSL1}(4). It is assumed that the first target test code count C_{MSL1}(4) is being selected, the read voltage optimization circuit 2152 then identifies the first test read voltage V(4)₄ corresponding to the selected first target test code count C_{MSL1}(4) as the target first test read voltage. In this example, the target first test read voltage V(4)₄ is the optimized read voltage corresponding to the transition read voltage V(1)₄ of the lower physical page.

Next, the read voltage optimization circuit 2152 replaces the transition read voltage V(1)₄ in the preset read voltage set V(1) by the target test read voltage V(4)₄ (e.g., by changing the voltage value of the fourth read voltage in the preset read voltage set V(1) to the voltage value of the target test read voltage V(4)₄), so as to change the preset read voltage set to the optimized read voltage set corresponding to the target physical page. At this point, the test code management circuit 2151 has completed the read voltage optimization operation corresponding to the target physical page (the lower physical page). The read voltage optimization circuit 2152 can record the obtained optimized read voltage set corresponding to the target physical page of the target word line.

Next, in step S26, after the read voltage optimization operation corresponding to the target physical page is completed, the processor 211 (or the read voltage management circuit unit 215) can use the optimized read voltage set to read the target word line.

For instance, in continuation to example above, when the processor 211 (or the read voltage management circuit unit 215) is using the optimized read voltage set to read the target word line, with use of the target test read voltage V(4)₄ in the optimized read voltage set in page-level, the processor 211 (or the read voltage management circuit unit 215) may identify the storage states of the lower physical page of the memory cells of the target word line more accurately. In other words, with the data reading method and the read voltage optimization operation provided by the present embodiment, the processor 211 (or the read voltage management circuit unit 215) can specify the target physical page to optimize the transition read voltage of the specified target physical page more precisely, so as to obtain the optimized read voltage corresponding to the specified target physical page. Later, when reading the word line containing the target physical page, not only can a more accurate data read result be obtained, the loading of the decoding operation may be reduced while improving the speed of the decoding operation.

It is worth noting that, in an embodiment, in the operation of determining whether the transition read voltage corresponding to the target test code needs the leftward adjustment or the rightward adjustment, the read voltage management circuit unit 215 can directly use the leftward adjustment or the rightward adjustment corresponding to a smaller test code count difference as the optimized read voltage corresponding to the transition read voltage. For example, in the example of FIG. 9A, the rightward adjusted transition read voltage corresponding to the smaller test code count difference D_{MSL1}(2,4) may be directly set as the optimized read voltage corresponding to the transition read voltage V(1)₄ of the lower physical page. Accordingly, the better read voltage corresponding to the transition read voltage of one physical page may be found quickly and simply by using three readings (e.g., by applying the read voltages V(1)₄, V(2)₄ and V(3)₄).

In this embodiment, the location of the optimized voltage is found by using the concept that the optimized read voltage should be located at the intersection between two threshold voltage distributions corresponding to two gray codes and the concept that there will only be a small change in the area at the intersection. Based on the concepts described above, persons with ordinary skilled in art can make modifications to read voltage optimization method/operation. However, those modifications are still within the spirit and scope of the invention.

Moreover, compared to the conventional approaches, the read voltage optimization method provided by the invention can optimize one or more transition read voltages of the specified transition read voltage without adjusting the transition read voltages of the other non-specified physical pages. In this way, because the invention focuses on the adjustment/testing of one or more transition read voltages on the target physical page, a total number of readings performed for the read voltage optimization operation can be significantly reduced (because it is not necessary to adjust/test the transition read voltages of other non-assigned physical page). In addition, if the test codes of the target physical page correspond to the transition read voltages (e.g., the example regarding the middle physical page in FIG. 10), the read voltage optimization operation provided by the invention can adjust/test the test read voltage sets corresponding to the transition read voltages at the same time (e.g., reading the target word line by using the rightward adjusted transition read voltages V(2)₂ and V(2)₆ at the same time), so as to further reduce the read count.

On the other hand, by using the read voltage optimization method provided in this embodiment to perform the read voltage optimization operation on all the physical pages of the target word line in sequence, the optimized read voltage set in word line level may also be obtained. For example, an optimization operation for the corresponding transition read voltage V(1)₄ is executed on the lower physical page (e.g., FIG. 9A) to obtain an optimized transition read voltage V(4)₄ corresponding to the lower physical page; the optimized transition read voltage V(4)₄ is used as a separate read voltage corresponding to a plurality of test codes of the middle physical page for performing a read voltage optimization operation on the middle physical page (e.g., FIG. 10) to obtain optimized transition read voltages V(2)₂ and V(2)₆ corresponding to the middle physical page; the optimized transition read voltages V(4)₄, V(2)₂ and V(2)₆ are used as separate read voltages corresponding to a plurality of test codes of the upper physical page for performing a read voltage optimization operation on the upper physical page (e.g., FIG. 11) to obtain optimized transition read voltages V(3)₁, V(3)₃, V(3)₅ and V(3)₇ corresponding to the upper physical page; lastly, the optimized transition read voltages V(4)₄, V(2)₂, V(2)₆, V(3)₁, V(3)₃, V(3)₅ and V(3)₇ are used as an optimized read voltage set of the target word line.

It is worth noting that, in the foregoing embodiments, the read voltage management circuit unit 215 is implemented in a hardware manner, but the invention is not limited thereto. For example, in an embodiment, the read voltage management circuit unit 215 may be implemented in software or firmware manner as a read voltage management program code module with the functions of the read voltage management circuit unit 215. The read voltage management program code module may include a test code management program code module and a read voltage optimization program code module. The test code management program code module is a program code module with the functions of the test code management circuit 2151; the read voltage optimization program code module is a program code module with the functions of the read voltage optimization circuit 2152. The processor 211 can access and execute the read voltage management program code module (or the test code management program code module and the read voltage optimization program code module) to implement the read voltage optimization method provided by the invention.

In summary, the data reading method, the storage controller and the storage device provided by the embodiments of the invention can execute the read voltage optimization operation corresponding to the target physical page of the target word line on any programmed target word line without preparing verified data. In the read voltage optimization operation, the storage controller identifies a plurality of test codes corresponding to the target physical page and one or more transition read voltages corresponding to the test codes, sets one or more test read voltage sets according to said one or more transition read voltages, and uses said one or more test read voltage sets to read the target word line to obtain a plurality of test code count difference sets. In this way, a target test read voltage (a.k.a. the optimized read voltage) may be identified from the test read voltages in each of the test read voltage sets according to the test code count difference sets, and the preset read voltage set may be changed to the optimized read voltage set corresponding to the target physical page and containing the optimized read voltages, so as to complete the read voltage optimization operation corresponding to the target physical page. After the read voltage optimization operation corresponding to the target physical page is completed, not only can the optimized read voltage set corresponding to the target physical page be found efficiently, the optimized read voltage set may further be used to read the target word line to improve accuracy of the data read from the target word line and improve overall efficiency in the data reading operation.

Although the present disclosure has been described with reference to the above embodiments, it will be apparent to one of ordinary skill in the art that modifications to the described embodiments may be made without departing from the spirit of the disclosure. Accordingly, the scope of the disclosure will be defined by the attached claims and not by the above detailed descriptions.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A data reading method, adapted to a storage device disposed with a rewritable non-volatile memory module, wherein the rewritable non-volatile memory module has a plurality of word lines, wherein each word line among the word lines is coupled to a plurality of memory cells, wherein each memory cell among the memory cells comprises a plurality of physical pages, each physical page among the physical pages is configured to be programmed as a bit value, and the method comprises:
selecting a target word line among the word lines of the rewritable non-volatile memory module, and performing a read voltage optimization operation corresponding to a target physical page among the physical pages on the target word line, wherein a plurality of target memory cells of the target word line are already programmed, and the read voltage optimization operation comprises steps of:
identifying P test codes corresponding to the target physical page, and identifying Q transition read voltages corresponding to the P test codes in a preset read voltage set according to the preset read voltage set corresponding to the target word line, wherein the Q transition read voltages are configured to divide a plurality of storage states of the target physical page, wherein P is a positive integer, and Q is a positive integer less than P;
setting Q test read voltage sets respectively corresponding to the Q transition read voltages, wherein each of the Q test read voltage sets comprises X test read voltages, and voltage values of the X test read voltages are set by a voltage value of the corresponding transition read voltage and a test voltage offset, wherein X is a positive integer;
using the Q transition read voltages and the corresponding Q test read voltage sets to read the target word line to obtain Q test code count difference sets corresponding to the Q test read voltage sets; and
obtaining an optimized read voltage set corresponding to the target physical page according to the Q test code count difference sets, so as to complete the read voltage optimization operation corresponding to the target physical page; and
using the optimized read voltage set to read the target word line after the read voltage optimization operation corresponding to the target physical page is completed.

2. The data reading method according to claim 1, wherein the step of using the Q transition read voltages and the corresponding Q test read voltage sets to read the target word line to obtain the Q test code count difference sets corresponding to the Q test read voltage sets comprises:
determining whether the P test codes correspond to one or more separate read voltages;
in response to determining that the P test codes do not correspond to any one of the separate read voltages, using the Q transition read voltages and the corresponding Q test read voltage sets to read the target word line to obtain the Q test code count difference sets corresponding to the Q test read voltage sets; and
in response to determining that the P test codes correspond to R separate read voltages, identifying voltage values of the R separate read voltages according to the preset read voltage set corresponding to the target word line, and using the R separate read voltages, the Q transition read voltages and the corresponding Q test read voltage sets to read the target word line to obtain the Q test code count difference sets corresponding to the Q test read voltage sets, wherein R is a positive integer.

3. The data reading method according to claim 2, wherein the P test codes corresponding to the target physical page are set by executing a test code setting operation corresponding to the target physical page, and the test code setting operation comprises steps of:
(1) identifying the Q transition read voltages corresponding to the target physical page according to the preset read voltage set corresponding to the target word line, wherein the storage states of the target physical page are divided by the Q transition read voltages;
(2) initially setting a plurality of target storage states according to M storage states of the target physical page, wherein a total number of the target storage states is M, and M is a positive integer greater than 1;
(3) determining whether a total number of the Q transition read voltages is equal to 1,
wherein in response to determining that the total number of the Q transition read voltages is equal to 1, a step (7) is executed;
wherein in response to determining that the total number of the Q transition read voltages is not equal to 1, a step (4) is executed;
(4) determining whether the target storage states are all different from each other according to a plurality of current bit value sets of the target storage states,
wherein in response to determining that the target storage states are all different from each other, the step (7) is executed,
wherein in response to determining that the target storage states are not all different from each other, a step (5) is executed;
(5) selecting a first candidate physical page arranged at a frontmost place from one or more not-yet-selected candidate physical pages in a plurality of candidate physical pages according to an order of the physical pages, and identifying a plurality of first candidate storage states of the first candidate physical page, wherein the first candidate storage states are divided by one or more candidate transition read voltages, wherein a step (6) follows on from the step (5);
(6) changing the target storage states from the current bit value sets to a plurality of adjusted bit value sets according to the first candidate storage states and the one or more candidate transition read voltages, wherein a total number of the adjusted bit value sets is greater than a total number of the current bit value sets, and a number of bit values in each of the adjusted bit value sets is greater than a number of bit values in each of the current bit value sets, wherein the step (4) follows on from the step (6); and
(7) setting the current bit value sets of the target storage states as a plurality of test codes corresponding to the target physical page to complete the test code setting operation corresponding to the target physical page.

4. The data reading method according to claim 3, wherein the step (3) in the test code setting operation comprises:
in response to determining that the total number of the Q transition read voltages is not equal to 1, not executing the step (4) but determining whether the total number of the Q transition read voltages is greater than a predetermined threshold, wherein in response to determining that the total number of the Q transition read voltages is not greater than the predetermined threshold, the step (4) is executed, wherein in response to determining that the total number of the Q transition read voltages is greater than the predetermined threshold, a plurality of gray codes of the memory cells are directly set as a plurality of test codes corresponding to the target physical page to complete the test code setting operation corresponding to the target physical page.

5. The data reading method according to claim 4, wherein if each memory cell of the rewritable non-volatile memory module comprises a lower physical page, a middle physical page and an upper physical page, a plurality of storage states of the lower physical page being divided by one read voltage, a plurality of storage states of the middle physical page being divided by two read voltages and a plurality of storage states of the upper physical page being divided by four read voltages, the rewritable non-volatile memory module is in a first read voltage mode, wherein a plurality of test codes corresponding to the lower physical page are set to “1” and “0”, a plurality of test codes corresponding to the middle physical page are set to “11”, “10”, “00” and “01”, and a plurality of test codes corresponding to the upper physical page are set to “111”, “110”, “100”, “101”, “001”, “000”, “010” and “011”, wherein if each memory cell of the rewritable non-volatile memory module comprises a lower physical page, a middle physical page and an upper physical page, a plurality of storage states of the lower physical page being divided by two read voltages, a plurality of storage states of the middle physical page being divided by three read voltages and a plurality of storage states of the upper physical page being divided by two read voltages, the rewritable non-volatile memory module is in a second read voltage mode, wherein a plurality of test codes corresponding to the lower physical page, the middle physical page and the upper physical page are all set to “111”, “110”, “100”, “101”, “001”, “000”, “010” and “011”.

6. The data reading method according to claim 2, wherein the step of setting the Q test read voltage sets respectively corresponding to the Q transition read voltages comprises: for a first transition read voltage among the Q transition read voltages, identifying a first target test code corresponding to the first transition read voltage among the test codes;
generating a leftward adjusted transition read voltage and a rightward adjusted transition read voltage according to the first transition read voltage and the test voltage offset, wherein a voltage value of the leftward adjusted transition read voltage is a difference obtain by subtracting the test voltage offset from a voltage value of the first transition read voltage, wherein a voltage value of the rightward adjusted transition read voltage is a sum obtain by adding the test voltage offset to the voltage value of the first transition read voltage;
using the first transition read voltage to read the target word line to identify a total number of the memory cells with the storage states being the first target test code in the target word line as an original first target test code count;
using the leftward adjusted transition read voltage to read the target word line to identify the total number of the memory cells with the storage states being the first target test code in the target word line as a leftward adjusted first target test code count, and using an absolute difference obtained by subtracting the leftward adjusted first target test code count from the original first target test code count as a leftward adjusted first target test code count difference;
using the rightward adjusted transition read voltage to read the target word line to identify the total number of the memory cells with the storage states being the first target test code in the target word line as a rightward adjusted first target test code count, and using an absolute difference obtained by subtracting the rightward adjusted first target test code count from the original first target test code count as a rightward adjusted first target test code count difference;
in response to the leftward adjusted first target test code count difference being less than the rightward adjusted first target test code count difference, determining that the first transition read voltage needs a leftward adjustment, and respectively subtracting 1 to X times the test voltage offset from the voltage value of the first transition read voltage to generate the X test read voltages of a first test read voltage set corresponding to the first transition read voltage; and
in response to the rightward adjusted target test code count difference being less than the leftward adjusted target test code count difference, determining that the first transition read voltage needs a rightward adjustment, and respectively adding 1 to X times the test voltage offset to the voltage value of the first transition read voltage to generate the X test read voltages of the first test read voltage set corresponding to the first transition read voltage.

7. The data reading method according to claim 6, wherein in response to determining that the P test codes do not correspond to any one of the separate read voltages, the step of using the Q transition read voltages and the corresponding Q test read voltage sets to read the target word line to obtain the Q test code count difference sets corresponding to the Q test read voltage sets comprises:
for the first transition read voltage among the Q transition read voltages, identifying the first target test code corresponding to the first transition read voltage among the test codes and the first test read voltage set corresponding to the first transition read voltage among the Q test read voltage sets;
using the first transition read voltage to read the target word line to identify the total number of the memory cells with the storage states being the first target test code in the target word line as the original first target test code count;
respectively using X first test read voltages of the first test read voltage set to read the target word line to obtain X first target test code counts, wherein a jth first target test code count among the X first target test code counts is a total number of the memory cells being the first target test code identified by using a jth first test read voltage among the X first test read voltages to read the target word line; and
calculating X first test code count differences for forming a first test code count difference set corresponding to the first test read voltage set among the Q test code count difference sets according to the original first target test code count and the X first target test code counts.

8. The data reading method according to claim 6, wherein in response to determining that the P test codes correspond to the R separate read voltages, the step of using the R separate read voltages, the Q transition read voltages and the corresponding Q test read voltage sets to read the target word line to obtain the Q test code count difference sets corresponding to the Q test read voltage sets comprises:
for the first transition read voltage among the Q transition read voltages, identifying the first target test code corresponding to the first transition read voltage among the test codes and the first test read voltage set corresponding to the first transition read voltage among the Q test read voltage sets;
first using the R separate read voltages to read the target word line, and then using the first transition read voltage to read the target word line to identify the total number of the memory cells with the storage states being the first target test code in the target word line as the original first target test code count;
respectively using X first test read voltages of the first test read voltage set to read the target word line to obtain X first target test code counts, wherein a jth first target test code count among the X first target test code counts is a total number of the memory cells being the first target test code identified by using a jth first test read voltage among the X first test read voltages to read the target word line; and
calculating X first test code count differences for forming a first test code count difference set corresponding to the first test read voltage set among the Q test code count difference sets according to the original first target test code count and the X first target test code counts.

9. The data reading method according to claim 8, wherein the step of obtaining the optimized read voltage set corresponding to the target physical page according to the Q test code count difference sets comprises:
identifying a target test read voltage from the X test read voltages of each of the Q test read voltage sets to obtain Q target test read voltages, and replacing the Q transition read voltages in the preset read voltage set by the Q target test read voltages to change the preset read voltage set to the optimized read voltage set, wherein the step of identifying the target test read voltage from the X test read voltages of each of the Q test read voltage sets comprises:
for the first test code count difference set corresponding to the first test read voltage set among the Q test code count difference sets and the first test read voltage set in the corresponding Q test read voltage sets, identifying a smallest one among the X first test code count differences as a target first test code count difference according to sizes of the X first test code count differences of the first test code count difference set; and
selecting one of two first target test code counts corresponding to the target first test code count difference, and identifying a target first test read voltage corresponding to the selected first target test code count from the X first test read voltages of the first test read voltage set.

10. The data encoding method according to claim 8, further comprising:
while using one of the Q transition read voltages to read the target word line, simultaneously using all the other transition read voltages among the Q transition read voltages to read the target word line;
while using one of the Q test read voltage sets to read the target word line, simultaneously using all the other test read voltage sets among the Q test read voltage sets to read the target word line; and
while using one of the R separate read voltages to read the target word line, simultaneously using all the other separate read voltages among the R separate read voltages to read the target word line.

11. A storage controller, configured to control a storage device having a rewritable non-volatile memory module, the storage controller comprising:
a connection interface circuit, configured to couple to a host system;
a memory interface control circuit, configured to couple to the rewritable non-volatile memory module, wherein the rewritable non-volatile memory module has a plurality of word lines, wherein each word line among the word lines is coupled to a plurality of memory cells, wherein each memory cell among the memory cells comprises a plurality of physical pages, and each physical page among the physical pages is configured to be programmed as a bit value;
a read voltage management circuit unit; and
a processor, coupled to the connection interface circuit, the memory interface control circuit and the read voltage management circuit unit,
wherein the processor selects a target word line among the word lines of the rewritable non-volatile memory module, and instructs the read voltage management circuit unit to perform a read voltage optimization operation corresponding to a target physical page among the physical pages on the target word line, wherein a plurality of target memory cells of the target word line are already programmed, and in the read voltage optimization operation,
the read voltage management circuit unit is configured to identify P test codes corresponding to the target physical page, and identify Q transition read voltages corresponding to the P test codes in a preset read voltage set according to the preset read voltage set corresponding to the target word line, wherein the Q transition read voltages are configured to divide a plurality of storage states of the target physical page, wherein P is a positive integer, and Q is a positive integer less than P,
wherein the read voltage management circuit unit is further configured to set Q test read voltage sets respectively corresponding to the Q transition read voltages, wherein each of the Q test read voltage sets comprises X test read voltages, and voltage values of the X test read voltages are set by a voltage value of the corresponding transition read voltage and a test voltage offset, wherein X is a positive integer,
wherein the read voltage management circuit unit is further configured to use the Q transition read voltages and the corresponding Q test read voltage sets to read the target word line to obtain Q test code count difference sets corresponding to the Q test read voltage sets,
wherein the read voltage management circuit unit is further configured to obtain an optimized read voltage set corresponding to the target physical page according to the Q test code count difference sets, so as to complete the read voltage optimization operation corresponding to the target physical page,
wherein the processor is further configured to use the optimized read voltage set to read the target word line after the read voltage optimization operation corresponding to the target physical page is completed.

12. The storage controller according to claim 11, wherein in the operation where the read voltage management circuit unit is further configured to use the Q transition read voltages and the corresponding Q test read voltage sets to read the target word line to obtain the Q test code count difference sets corresponding to the Q test read voltage sets,
the read voltage management circuit unit determines whether the P test codes correspond to one or more separate read voltages,
wherein in response to determining that the P test codes do not correspond to any one of the separate read voltages, the read voltage management circuit unit uses the Q transition read voltages and the corresponding Q test read voltage sets to read the target word line to obtain the Q test code count difference sets corresponding to the Q test read voltage sets,
wherein in response to determining that the P test codes correspond to R separate read voltages, the read voltage management circuit unit identifies voltage values of the R separate read voltages according to the preset read voltage set corresponding to the target word line, and uses the R separate read voltages, the Q transition read voltages and the corresponding Q test read voltage sets to read the target word line to obtain the Q test code count difference sets corresponding to the Q test read voltage sets, wherein R is a positive integer.

13. The storage controller according to claim 12, wherein the read voltage management circuit unit executes a test code setting operation corresponding to the target physical page to set the P test codes corresponding to the target physical page, wherein in the test code setting operation, the read voltage management circuit unit executes steps of:
(1) identifying the Q transition read voltages corresponding to the target physical page according to the preset read voltage set corresponding to the target word line, wherein the storage states of the target physical page are divided by the Q transition read voltages;
(2) initially setting a plurality of target storage states according to M storage states of the target physical page, wherein a total number of the target storage states is M, and M is a positive integer greater than 1;
(3) determining whether a total number of the Q transition read voltages is equal to 1,
wherein in response to determining that the total number of the Q transition read voltages is equal to 1, a step (7) is executed;
wherein in response to determining that the total number of the Q transition read voltages is not equal to 1, a step (4) is executed;
(4) determining whether the target storage states are all different from each other according to a plurality of current bit value sets of the target storage states,
wherein in response to determining that the target storage states are all different from each other, the step (7) is executed,
wherein in response to determining that the target storage states are not all different from each other, a step (5) is executed;
(5) selecting a first candidate physical page arranged at a frontmost place from one or more not-yet-selected candidate physical pages in a plurality of candidate physical pages according to an order of the physical pages, and identifying a plurality of first candidate storage states of the first candidate physical page, wherein the first candidate storage states are divided by one or more candidate transition read voltages, wherein a step (6) follows on from the step (5);
(6) changing the target storage states from the current bit value sets to a plurality of adjusted bit value sets according to the first candidate storage states and the one or more candidate transition read voltages, wherein a total number of the adjusted bit value sets is greater than a total number of the current bit value sets, and a number of bit values in each of the adjusted bit value sets is greater than a number of bit values in each of the current bit value sets, wherein the step (4) follows on from the step (6); and
(7) setting the current bit value sets of the target storage states as a plurality of test codes corresponding to the target physical page to complete the test code setting operation corresponding to the target physical page.

14. The storage controller according to claim 13, wherein the step (3) in the test code setting operation comprises:
in response to determining that the total number of the Q transition read voltages is not equal to 1, not executing the step (4) but determining whether the total number of the Q transition read voltages is greater than a predetermined threshold,
wherein in response to determining that the total number of the Q transition read voltages is not greater than the predetermined threshold, the step (4) is executed,
wherein in response to determining that the total number of the Q transition read voltages is greater than the predetermined threshold, a plurality of gray codes of the memory cells are directly set as a plurality of test codes corresponding to the target physical page to complete the test code setting operation corresponding to the target physical page.

15. The storage controller according to claim 14,
wherein if each memory cell of the rewritable non-volatile memory module comprises a lower physical page, a middle physical page and an upper physical page, a plurality of storage states of the lower physical page being divided by one read voltage, a plurality of storage states of the middle physical page being divided by two read voltages and a plurality of storage states of the upper physical page being divided by four read voltages, the rewritable non-volatile memory module is in a first read voltage mode, wherein a plurality of test codes corresponding to the lower physical page are set to “1” and “0”, a plurality of test codes corresponding to the middle physical page are set to “11”, “10”, “00” and “01”, and a plurality of test codes corresponding to the upper physical page are set to “111”, “110”, “100”, “101”, “001”, “000”, “010” and “011”,
wherein if each memory cell of the rewritable non-volatile memory module comprises the lower physical page, the middle physical page and the upper physical page, a plurality of storage states of the lower physical page being divided by two read voltages, a plurality of storage states of the middle physical page being divided by three read voltages and a plurality of storage states of the upper physical page being divided by two read voltages, the rewritable non-volatile memory module is in a second read voltage mode, wherein a plurality of test codes corresponding to the lower physical page, the middle physical page and the upper physical page are all set to “111”, “110”, “100”, “101”, “001”, “000”, “010” and “011”.

16. The storage controller according to claim 12, wherein in the operation where the read voltage management circuit unit is further configured to set the Q test read voltage sets respectively corresponding to the Q transition read voltages,
for a first transition read voltage among the Q transition read voltages, the read voltage management circuit unit identifies a first target test code corresponding to the first transition read voltage among the test codes,
wherein the read voltage management circuit unit generates a leftward adjusted transition read voltage and a rightward adjusted transition read voltage according to the first transition read voltage and the test voltage offset, wherein a voltage value of the leftward adjusted transition read voltage is a difference obtain by subtracting the test voltage offset from a voltage value of the first transition read voltage, wherein a voltage value of the rightward adjusted transition read voltage is a sum obtain by adding the test voltage offset to the voltage value of the first transition read voltage,
wherein the read voltage management circuit unit uses the first transition read voltage to read the target word line to identify the total number of the memory cells with the storage states being the first target test code in the target word line as an original first target test code count,
wherein the read voltage management circuit unit uses the leftward adjusted transition read voltage to read the target word line to identify the total number of the memory cells with the storage states being the first target test code in the target word line as a leftward adjusted first target test code count, and uses an absolute difference obtained by subtracting the leftward adjusted first target test code count from the original first target test code count as a leftward adjusted first target test code count difference,
wherein the read voltage management circuit unit uses the rightward adjusted transition read voltage to read the target word line to identify the total number of the memory cells with the storage states being the first target test code in the target word line as a rightward adjusted first target test code count, and uses an absolute difference obtained by subtracting the rightward adjusted first target test code count from the original first target test code count as a rightward adjusted first target test code count difference,
wherein in response to the leftward adjusted first target test code count difference being less than the rightward adjusted first target test code count difference, the read voltage management circuit unit determines that the first transition read voltage needs a leftward adjustment, and respectively subtracts 1 to X times the test voltage offset from the voltage value of the first transition read voltage to generate the X test read voltages of a first test read voltage set corresponding to the first transition read voltage,
wherein in response to the rightward adjusted target test code count difference being less than the leftward adjusted target test code count difference, the read voltage management circuit unit determines that the first transition read voltage needs a rightward adjustment, and respectively adds 1 to X times the test voltage offset to the voltage value of the first transition read voltage to generate the X test read voltages of the first test read voltage set corresponding to the first transition read voltage.

17. The storage controller according to claim 16, wherein in response to determining that the P test codes do not correspond to any one of the separate read voltages, in the operation where the read voltage management circuit unit is further configured to use the Q transition read voltages and the corresponding Q test read voltage sets to read the target word line to obtain the Q test code count difference sets corresponding to the Q test read voltage sets,
for the first transition read voltage among the Q transition read voltages, the read voltage management circuit unit identifies the first target test code corresponding to the first transition read voltage among the test codes and the first test read voltage set corresponding to the first transition read voltage among the Q test read voltage sets,
wherein the read voltage management circuit unit uses the first transition read voltage to read the target word line to identify the total number of the memory cells with the storage states being the first target test code in the target word line as the original first target test code count,
wherein the read voltage management circuit unit respectively uses X first test read voltages of the first test read voltage set to read the target word line to obtain X first target test code counts, wherein a jth first target test code count among the X first target test code counts is a total number of the memory cells being the first target test code identified by using a jth first test read voltage among the X first test read voltages to read the target word line,
wherein the read voltage management circuit unit calculates X first test code count differences for forming a first test code count difference set corresponding to the first test read voltage set among the Q test code count difference sets according to the original first target test code count and the X first target test code counts.

18. The storage controller according to claim 16, wherein in response to determining that the P test codes correspond to the R separate read voltages, in the operation where the read voltage management circuit unit is further configured to use the R separate read voltages, the Q transition read voltages and the corresponding Q test read voltage sets to read the target word line to obtain the Q test code count difference sets corresponding to the Q test read voltage sets,
for the first transition read voltage among the Q transition read voltages, the read voltage management circuit unit identifies the first target test code corresponding to the first transition read voltage among the test codes and the first test read voltage set corresponding to the first transition read voltage among the Q test read voltage sets,
wherein the read voltage management circuit unit first uses the R separate read voltages to read the target word line, and then uses the first transition read voltage to read the target word line to identify the total number of the memory cells with the storage states being the first target test code in the target word line as the original first target test code count,
wherein the read voltage management circuit unit respectively uses X first test read voltages of the first test read voltage set to read the target word line to obtain X first target test code counts, wherein a jth first target test code count among the X first target test code counts is a total number of the memory cells being the first target test code identified by using a jth first test read voltage among the X first test read voltages to read the target word line,
wherein the read voltage management circuit unit calculates X first test code count differences for forming a first test code count difference set corresponding to the first test read voltage set among the Q test code count difference sets according to the original first target test code count and the X first target test code counts.

19. The storage controller according to claim 18, wherein in the operation where the read voltage management circuit unit is further configured to obtain the optimized read voltage set corresponding to the target physical page according to the Q test code count difference sets,
the read voltage management circuit unit identifies a target test read voltage from the X test read voltages of each of the Q test read voltage sets to obtain Q target test read voltages, and replaces the Q transition read voltages in the preset read voltage set by the Q target test read voltages to change the preset read voltage set to the optimized read voltage set, wherein in the operation of identifying the target test read voltage from the X test read voltages of each of the Q test read voltage sets,
for the first test code count difference set corresponding to the first test read voltage set among the Q test code count difference sets and the first test read voltage set in the corresponding Q test read voltage sets, the read voltage management circuit unit identifies a smallest one among the X first test code count differences as a target first test code count difference according to sizes of the X first test code count differences of the first test code count difference set,
wherein the read voltage management circuit unit selects one of two first target test code counts corresponding to the target first test code count difference, and identifies a target first test read voltage corresponding to the selected first target test code count from the X first test read voltages of the first test read voltage set.

20. The storage controller according to claim 18, wherein
while the read voltage management circuit unit is using one of the Q transition read voltages to read the target word line, the read voltage management circuit unit simultaneously uses all the other transition read voltages among the Q transition read voltages to read the target word line,
wherein while the read voltage management circuit unit is using one of the Q test read voltage sets to read the target word line, the read voltage management circuit unit simultaneously uses all the other test read voltage sets among the Q test read voltage sets to read the target word line,
wherein while the read voltage management circuit unit is using one of the R separate read voltages to read the target word line, the read voltage management circuit unit simultaneously uses all the other separate read voltages among the R separate read voltages to read the target word line.

21. A storage device, the storage device comprising:
a rewritable non-volatile memory module, wherein the rewritable non-volatile memory module has a plurality of word lines, wherein each of the word lines is coupled to a plurality of memory cells, wherein each memory cell among the memory cells comprises a plurality of physical pages, and each physical page among the physical pages is configured to be programmed as a bit value;
a memory interface control circuit, configured to couple to the rewritable non-volatile memory module; and
a processor, coupled to the memory interface control circuit, wherein the processor loads in and executes a read voltage management program code module to realize a data reading method, and the data reading method comprises steps of:
selecting a target word line among the word lines of the rewritable non-volatile memory module, and performing a read voltage optimization operation corresponding to a target physical page among the physical pages on the target word line, wherein a plurality of target memory cells of the target word line are already programmed, and the read voltage optimization operation comprises steps of:
identifying P test codes corresponding to the target physical page, and identifying Q transition read voltages corresponding to the P test codes in a preset read voltage set according to the preset read voltage set corresponding to the target word line, wherein the Q transition read voltages are configured to divide a plurality of storage states of the target physical page, wherein P is a positive integer, and Q is a positive integer less than P;
setting Q test read voltage sets respectively corresponding to the Q transition read voltages, wherein each of the Q test read voltage sets comprises X test read voltages, and voltage values of the X test read voltages are set by a voltage value of the corresponding transition read voltage and a test voltage offset, wherein X is a positive integer;
using the Q transition read voltages and the corresponding Q test read voltage sets to read the target word line to obtain Q test code count difference sets corresponding to the Q test read voltage sets; and
obtaining an optimized read voltage set corresponding to the target physical page according to the Q test code count difference sets, so as to complete the read voltage optimization operation corresponding to the target physical page; and
using the optimized read voltage set to read the target word line after the read voltage optimization operation corresponding to the target physical page is completed.
